(19) United States
(12) Patent Application Publication
(10) Pub. No.: US 2023/0354623 A1
(43) Pub. Date: Nov. 2, 2023

(54) PHOTOCURRENT MULTIPLICATION DEVICE AND IMAGING DEVICE

(71) Applicant: Panasonic Intellectual Property Management Co., Ltd., Osaka (JP)

(72) Inventors: HIROAKI IIJIMA, Nara (JP); MASAYA HIRADE, Osaka (JP); YUKO KISHIMOTO, Osaka (JP); MASUMI IZUCHI, Osaka (JP)

(21) Appl. No.: 18/346,759

(22) Filed: Jul. 3, 2023

Related U.S. Application Data
(63) Continuation of application No. PCT/JP2021/048517, filed on Dec. 27, 2021.

(30) Foreign Application Priority Data
Jan. 22, 2021 (JP) 2021-008700

(51) Int. Cl. H10K 30/65; H10K 85/30; H10K 30/81; H10K 30/80; H10K 39/32

(52) U.S. Cl. CPC H10K 30/65; H10K 85/311; H10K 30/81; H10K 30/865; H10K 39/32

(57) ABSTRACT

A photocurrent multiplication device having an external quantum efficiency of 100% or more includes at least one first electrode, at least one second electrode facing the at least one first electrode, and a photoelectric conversion film that is located between the at least one first electrode and the at least one second electrode and that includes a donor material and an acceptor material. The photoelectric conversion film at least partially has a sea-island structure in which the donor material is interspersed in the photoelectric conversion film.

### BACKGROUND

### 1. Technical Field

The present disclosure relates to a photocurrent multiplication device and an imaging device.

### 2. Description of the Related Art

Organic semiconductor materials have physical properties, functions, and so on that are not possessed by existing inorganic semiconductor materials such as silicon. Accordingly, for example, as described in JANA ZAUMSEIL et al., “Electron and Ambipolar Transport in Organic Field-Effect Transistors”, Chemical Reviews, American Chemical Society, 2007, Vol. 107, No. 4, pp. 1296-1323 (Non-Patent Literature 1) and Japanese Unexamined Patent Application Publication No. 2010-232410, recently, organic semiconductor materials have been actively studied as semiconductor materials that can realize new semiconductor devices and electronic equipment.

For example, studies have been conducted to realize a photoelectric conversion device by reducing the thickness of a film of an organic semiconductor material and employing the thinned film as a photoelectric conversion material. As described in SERAP GUNES et al., “Conjugated Polymer-Based Organic Solar Cells”, Chemical Reviews, American Chemical Society, 2007, Vol. 107, No. 4, pp. 1324-1338 (Non-Patent Literature 2), a photoelectric conversion device employing an organic thin film can be utilized, for example, as an organic thin film solar cell by extracting electric charges, which are carriers generated by light, as energy. In addition, as described in Japanese Unexamined Patent Application Publication No. 2003-234460, a photoelectric conversion device employing an organic thin film can be utilized as an optical sensor, such as an imaging device, by extracting electric charges generated by light as electric signals.

As organic semiconductor materials sensitive to near-infrared light, phthalocyanine derivatives and naphthalocyanine derivatives are known. For example, Japanese Patent No. 5216279 discloses naphthalocyanine derivatives having a maximum absorption wavelength of 805 to 825 nm.

As devices to be used in optical sensors and so on, in addition to photoelectric conversion devices in which electric charges generated by photoelectric conversion are extracted, photocurrent multiplication devices utilizing a photocurrent multiplication phenomenon are known. Examples of the photocurrent multiplication device include an avalanche photodiode (APD) and a photocurrent multiplication device utilizing a tunneling current from an electrode.

The photocurrent multiplication device can detect multiplied current by changing the conductivity of the device with incident light and transporting electric charges in an amount higher than that of the electric charges generated from photons of the incident light utilizing electron injection from an electrode.

Japanese Patent Nos. 3426211 and 6219172 disclose a photocurrent multiplication device utilizing an organic semiconductor and a photocurrent multiplication device employing an inorganic material as a sensitizer, respectively, as photocurrent multiplication devices utilizing a photocurrent multiplication phenomenon.

### SUMMARY

In one general aspect, the techniques disclosed here feature a photocurrent multiplication device having an external quantum efficiency of 100% or more. The photocurrent multiplication device comprises at least one first electrode, at least one second electrode facing the at least one first electrode, and a photoelectric conversion film located between the at least one first electrode and the at least one second electrode and including a donor material and an acceptor material. The photoelectric conversion film at least partially has a sea-island structure in which the donor material is interspersed in the photoelectric conversion film.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1A is a schematic cross-sectional view showing an example of a photocurrent multiplication device according to an embodiment;

FIG. 1B is a schematic view showing a sea-island structure in a photoelectric conversion film according to an embodiment;

FIG. 2 is a schematic cross-sectional view showing another example of a photocurrent multiplication device according to an embodiment;

FIG. 3 is a diagram showing an example of an energy band diagram of the photocurrent multiplication device shown in FIG. 2;

FIG. 4 is a diagram showing an example of a circuit constitution of an imaging device according to an embodiment;

FIG. 5 is a schematic cross-sectional view showing an example of the device structure of a pixel in an imaging device according to an embodiment;

FIG. 6A is a diagram of an absorption spectrum of the photoelectric conversion film of Example 3;

FIG. 6B is a diagram showing the measurement results of photoelectron spectroscopic measurement of the photoelectric conversion film of Example 3;

FIG. 7A is a diagram showing absorption spectra of the photoelectric conversion films of Examples 4 to 8;

FIG. 7B is a diagram showing the measurement results of photoelectron spectroscopic measurement of the photoelectric conversion film of Example 4;

FIG. 8 is a diagram showing the measurement results of spectral sensitivity characteristics of the photocurrent multiplication device of Example 9; and

FIG. 9 is a diagram showing the measurement results of spectral sensitivity characteristics of the photocurrent multiplication devices of Examples 11 to 15.

### DETAILED DESCRIPTIONS

Underlying Knowledge Forming Basis of the Present Disclosure

In photoelectric conversion films employing materials such as organic semiconductors, in order to achieve highly efficient photoelectric conversion, for example, a bulk heterojunction structure in which a donor material and an acceptor material are mixed is employed. However, in electric charge extraction by an ordinary photoelectric conversion process, electrons and holes, which are electric charges generated in the photoelectric conversion film by absorption of light, are separated, and the separated electric charges are extracted by electrodes. Accordingly, in principle, only one electric charge is extracted for one photon. In contrast, in photoelectric conversion utilizing a photocurrent multiplication phenomenon, when the state of the photoelectric conversion film is changed by absorption of light, electric charge movement occurs due to electric charge injection from an electrode, and light is converted into electric charges. Accordingly, one or more electric charges can be detected for one photon. That is, it means that external quantum efficiency (EQE) can be 100% or more.

Lingliang Li et al., “Achieving EQE of 16,700% in P3HT5PC71BM based photodetectors by trap-assisted photomultiplication”, Scientific Reports, www.nature.com, 2015, Vol. 5, No. 9181 (Non-Patent Literature 5) discloses a configuration in which organic semiconductor donor material P3HT and acceptor material PCBM ([6,6]-phenyl-C61-butyric acid methyl ester) are used, and the ratio of the acceptor material is reduced to trap electrons in a photoelectric conversion film and cause a photocurrent multiplication phenomenon, and holes are injected into the photoelectric conversion film. However, it has been reported that in the configuration disclosed in Non-Patent Literature 5, the dark current is relatively large.

On the other hand, S X. Luo et all., “Insight into trap state dynamics for exploiting current multiplication in organic photodetectors”, Phys. Status Solidi RRL Willey Online Library, 2016, Vol. 10, No. 6, pp. 485-492 (Non-Patent Literature 4) and Dezhi Yang et al., “Deep ultraviolet-to-NIR broad spectral response organic photodetectors with large gain”, Journal of Materials Chemistry C, American Chemical Society, 2016, Vol. 4, pp. 2160-2164 (Non-Patent Literature 6) disclose a configuration in which a blocking layer is disposed near the photoelectric conversion film to stop the electric charges at the interface with the blocking layer, and thereby the energy band structure of the photoelectric conversion film is bent, and a photocurrent multiplication phenomenon is caused by electric charge injection from an electrode. However, also in this configuration, the dark current is high, 5 mA/cm² in Non-Patent Literature 4 and 0.2 mA/cm² in Non-Patent Literature 6. In addition, since electric charges are accumulated at the blocking layer interface, there are problems in reliability and so on.

The present inventors have found that in a photocurrent multiplication device, the structure of the photoelectric conversion film and the electric charges injected from an electrode affect the dark current. Specifically, the present inventors have found that in a photocurrent multiplication device, the dark current can be reduced by allowing holes to remain in the photoelectric conversion film and transporting injected electrons. Accordingly, the present disclosure provides a photocurrent multiplication device that can reduce dark current and an imaging device employing the device.

The outline of an aspect of the present disclosure is as follows.

The photocurrent multiplication device according to an aspect of the present disclosure is a photocurrent multiplication device having an external quantum efficiency of 100% or more and including at least one first electrode, at least one second electrode that faces the at least one first electrode, and a photoelectric conversion film that is located between the at least one first electrode and the at least one second electrode and that includes a donor material and an acceptor material. The photoelectric conversion film at least partially has a sea-island structure in which the donor material is interspersed in the photoelectric conversion film.

Consequently, holes generated in the photoelectric conversion film by incidence of light remain in the photoelectric conversion film, the energy band of the photoelectric conversion film is changed to allow electrons to be injected from a first electrode, and the electrons flow into the photocurrent multiplication device. By such a configuration of transporting electrons, the photocurrent multiplication device has a high external quantum efficiency utilizing a photocurrent multiplication phenomenon and can reduce dark current. In addition, since the photoelectric conversion film at least partially has a sea-island structure in which the donor material is interspersed in the photoelectric conversion film, electrons flow during the bright time as described above, but the paths in which electric charges flow are lessened during the dark time, and the photocurrent multiplication device can reduce dark current.

The photocurrent multiplication device according to another aspect of the present disclosure is a photocurrent multiplication device having an external quantum efficiency of 100% or more and including at least one first electrode, at least one second electrode that faces the at least one first electrode, a photoelectric conversion film that is located between the at least one first electrode and the at least one second electrode and that includes a donor material and an acceptor material, and a buffer layer that is located between the at least one first electrode and the photoelectric conversion film. The photoelectric conversion film has a bulk heterojunction structure. The difference between the lowest unoccupied molecular orbital (LUMO) energy level of the buffer layer and the LUMO energy level of the photoelectric conversion film is 0.5 eV or less.

Consequently, holes generated in the photoelectric conversion film by incidence of light remain in the photoelectric conversion film, the energy band of the photoelectric conversion film is changed to allow electrons to be injected from a first electrode, and the electrons flow into the photocurrent multiplication device. By such a configuration of transporting electrons, the photocurrent multiplication device has a high external quantum efficiency utilizing a photocurrent multiplication phenomenon and can reduce dark current. In addition, the photocurrent multiplication device including a buffer layer having a small LUMO energy level different from that of the photoelectric conversion film can reduce dark current while suppressing a reduction in the external quantum efficiency.

In addition, for example, the weight ratio of the donor material to the acceptor material in the photoelectric conversion film may be 3/7 or less.

Consequently, holes generated in the photoelectric conversion film by incidence of light remain in the photoelectric conversion film, the energy band of the photoelectric conversion film is changed to allow electrons to be injected from a first electrode, and the electrons flow into the photocurrent multiplication device. By such a configuration of transporting electrons, the photocurrent multiplication device has a high external quantum efficiency utilizing a photocurrent multiplication phenomenon and can reduce dark current.

In addition, for example, the weight ratio of the donor material to the acceptor material in the photoelectric conversion film may be 1/9 or less.

Consequently, the photoelectric conversion film is likely to form a sea-island structure in which the donor material is interspersed in the photoelectric conversion film to increase the proportion of the sea-island structure in the photoelectric conversion film. As a result, the electrons injected from the first electrode are likely to flow in the photoelectric conversion film, and the photocurrent multiplication device can further improve the external quantum efficiency. In addition, during the dark time, the paths in which electric charges flow in the photoelectric conversion film are lessened, and the photocurrent multiplication device can further reduce dark current.

In addition, for example, the donor material may be an organic semiconductor material.

Consequently, it is possible to realize a photocurrent multiplication device having spectral sensitivity characteristics at various wavelengths depending on the absorption wavelength of the organic semiconductor material.

In addition, for example, the donor material may be a low-molecular material.

Consequently, since the molecular weight of the donor material is small, the donor material easily moves during, for example, the formation of the photoelectric conversion film, and the photoelectric conversion film is likely to form a sea-island structure.

For example, the donor material may include at least one substituent not including a π-conjugated system.

The energy level that allows the donor material to trap holes is generally thought to be the highest occupied molecular orbital (HOMO) energy level, but the molecular orbital of HOMO spreads in a π-conjugated system. Accordingly, when the donor material includes a substituent not having a π-conjugated system, the substituent almost does not contribute to the molecular orbital of HOMO. Accordingly, when the donor material traps holes, the substituent acts as a barrier when a hole is trapped to broaden the distance between the molecular orbital of the molecule trapping the hole and the molecular orbital of a molecule adjacent to the molecule, resulting in a difficulty in movement of holes. As a result, a photocurrent multiplication phenomenon that is caused by trapping of holes by the donor material efficiently occurs.

For example, the donor material may include at least one alkyl group including 4 or more carbon atoms.

Consequently, when the donor material traps a hole, since the alkyl group broadens the distance between the molecular orbital of the molecule trapping the hole and the molecular orbital of a molecule adjacent to the molecule, the trapped hole is suppressed from moving to the adjacent molecule, and a photocurrent multiplication phenomenon that is caused by trapping holes efficiently occurs.

In addition, the donor material may include a phthalocyanine skeleton or a naphthalocyanine skeleton.

Consequently, a material having a phthalocyanine skeleton or a naphthalocyanine skeleton is likely to have a longer absorption peak wavelength, and a photocurrent multiplication device utilizing the photocurrent multiplication phenomenon in a near-infrared light region is likely to be realized.

In addition, since a material having a phthalocyanine skeleton or a naphthalocyanine skeleton has a high extinction coefficient of the Q band of a near-infrared light region, even when it is used as a donor material becoming islands of a sea-island structure, sufficient absorption is achieved.

In addition, in a wavelength region of 760 nm or more, the external quantum efficiency of the photocurrent multiplication device may be 100% or more.

Consequently, the photocurrent multiplication device can achieve a high external quantum efficiency in a near-infrared light region.

For example, the photoelectric conversion film may have a structure in which the donor material is dispersed throughout the photoelectric conversion film.

Consequently, since the electric charges generated by photoelectric conversion are not biased in the photoelectric conversion film, the material constituting the photoelectric conversion film is prevented from deteriorating, and the reliability of the photocurrent multiplication device is improved.

In addition, when the photocurrent multiplication device is used in an imaging device, since the electron charges generated by photoelectric conversion are present throughout the device and thereby the probability of recombination of electric charges generated by photoelectric conversion by the next frame in imaging by the imaging device is also increased, resulting in an improvement in the afterimage characteristics.

For example, at least one selected from the group consisting of the at least one first electrode and the at least one second electrode may be in contact with the photoelectric conversion film.

Consequently, since the electrode and the photoelectric conversion film can directly give and receive electrons, electrons are more likely to flow in the photoelectric conversion film, and the photocurrent multiplication device can improve the external quantum efficiency.

The photocurrent multiplication device may further include a buffer layer located between the at least one first electrode and the photoelectric conversion film or between the at least one second electrode and the photoelectric conversion film.

Consequently, the photocurrent multiplication device can further reduce dark current.

The work function of the at least one first electrode may be deeper by 0.6 eV or more than the LUMO energy level of the photoelectric conversion film.

Consequently, the photocurrent multiplication device can further reduce dark current.

The at least one first electrode or the at least one second electrode may include a plurality of pixel electrodes, and the plurality of pixel electrodes may be disposed in an array.

Consequently, the photocurrent multiplication device can perform electric charge extraction as an image sensor that can perform image output.

The electron injected from the at least one first electrode into the photoelectric conversion film is transported toward the at least one second electrode, and thereby the external quantum efficiency of the photocurrent multiplication device may become 100% or more.

An imaging device according to an aspect of the present disclosure includes a substrate and a pixel including an electric charge detection circuit disposed in the substrate, a photoelectric converter provided on the substrate, and an electric charge storage node electrically connected to the electric charge detection circuit and the photoelectric converter. The photoelectric converter includes the photocurrent multiplication device.

Consequently, the imaging device includes the photocurrent multiplication device in the photoelectric converter and thereby has a high external quantum efficiency and also can reduce dark current.

In addition, the external quantum efficiency of the photocurrent multiplication device may be 200% or more in a wavelength region of 760 nm or more.

The photocurrent multiplication device may have an absorption peak in a wavelength region of 760 nm or more.

The photocurrent multiplication device may have an absorption peak within a wavelength region of 880 nm or more.

Embodiments will now be specifically described with reference to the drawings.

Incidentally, the embodiments described below are all generic or specific examples. The numbers, shapes, materials, components, arrangement positions and connection configurations of components, steps, order of steps, and so on are examples and are not intended to limit the present disclosure. In addition, among the components in the following embodiments, the components that are not mentioned in independent claims will be described as optional components. Each drawing is not necessarily strictly illustrated. Accordingly, for example, in each drawing, the scale or the like is not necessarily identical. In addition, in each drawing, substantially the same configurations are given with the same reference signs, and overlapping explanations are omitted or simplified.

In the present specification, terms indicating relationships between elements, terms indicating shapes of elements, and numerical ranges are not expressions that only have strict meanings and are expressions that include substantially the same range, for example, a difference of about several percent.

In addition, in the present specification, the terms “upper” and “lower” do not refer to the upward (vertically upward) and the downward (vertically downward) in absolute spatial perception and are used as terms that are defined by relative positional relationship based on the stacking order in a stacking structure. Specifically, the light receiving side of an imaging device is referred to as “upper”, and the side opposite to the light receiving side is referred to as “lower”. Incidentally, the terms such as “upper” and “lower” are used only to specify the mutual arrangement of members and are not intended to limit the posture of an imaging device when it is used. In addition, the terms “upper” and “lower” are applied not only to when two components are arranged with a gap therebetween and another component is present between two components but also to when two components are arranged to adhere to each other and are in contact with each other.

### EMBODIMENTS

Embodiments of a photocurrent multiplication device and an imaging device utilizing a photocurrent multiplication phenomenon according to the present disclosure will now be described.

### Composition

First, a composition according to the present embodiment will be described. The composition according to the present embodiment is used as, for example, a donor material contained in a photoelectric conversion film of a photocurrent multiplication device utilizing a photocurrent multiplication phenomenon. The composition is not particularly limited as long as it is a p-type semiconductor that can be a donor material and is a material such as an organic semiconductor, an inorganic semiconductor, or a quantum dot or compound semiconductor. Hereinafter, as examples of the organic semiconductor, phthalocyanine and naphthalocyanine derivatives will be particularly described.

The donor material includes at least one of naphthalocyanine derivatives and phthalocyanine derivatives represented by the following formulae (1) and (2), respectively:

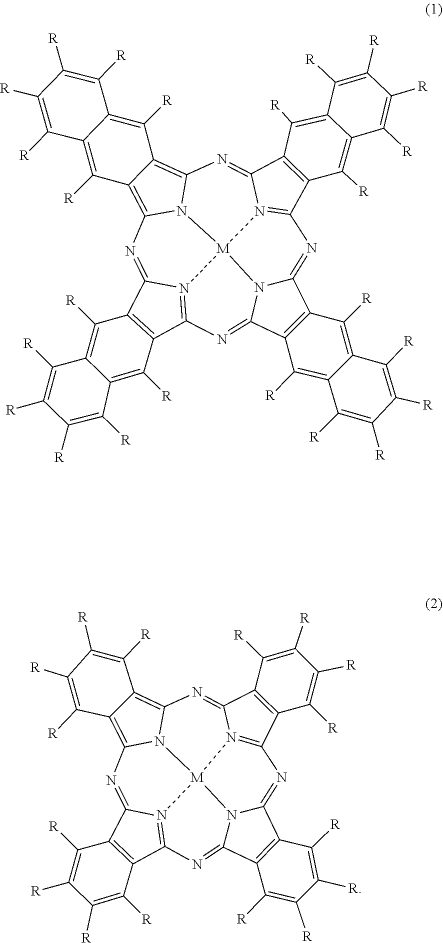

Each side chain R in the formulae (1) and (2) above is not particularly limited and may be any substituent. The M located at the center of the skeleton in each of the formulae (1) and (2) may be a metal or may be H₂ or the like. The naphthalocyanine derivative and the phthalocyanine derivative of the formulae (1) and (2) may have a substituent, a so-called axial ligand, in a roughly vertical direction through the central metal M.

The naphthalocyanine derivative is, for example, a compound represented by the following formula (3):

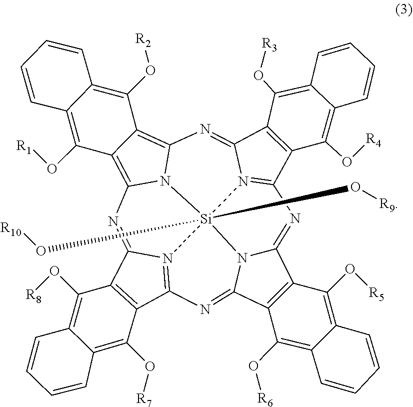

For example, in the naphthalocyanine derivative represented by the formula (3), R₁ to R₈ are each independently an alkyl group. In the formula (3), R₉ and R₁₀ are each a substituent bonded to the central metal through an oxygen atom roughly vertically with respect to the naphthalocyanine skeleton.

The phthalocyanine derivative is, for example, a compound represented by the following formula (4):

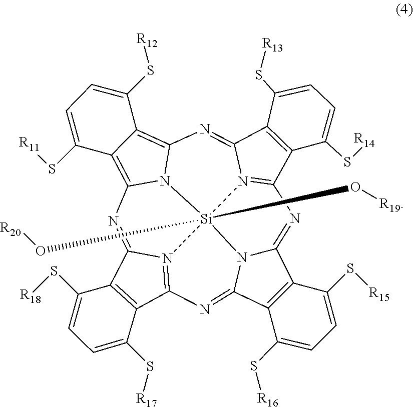

For example, in the phthalocyanine derivative represented by the formula (4), R₁₁ to R₁₈ are each independently an alkyl group. In the formula (4), R₁₉ and R₂₀ are each a substituent bonded to the central metal through an oxygen atom roughly vertically with respect to the phthalocyanine skeleton.

The naphthalocyanine derivative represented by the formula (3) and the phthalocyanine derivative represented by the formula (4) include silicon (Si) as the central metal and have an axial ligand-type structure including two axial ligands above and below with respect to the molecular plane. Consequently, the intermolecular interaction is relieved, and the dark current when the composition is used in a photocurrent multiplication device can be suppressed.

The composition according to the present embodiment can have a high light absorption property in, for example, a near-infrared light region of a wavelength of 760 nm or more and can have an absorption peak particularly in a wavelength of 880 nm or more, by including the naphthalocyanine derivative represented by the formula (3) or the phthalocyanine derivative represented by the formula (4). Accordingly, a photocurrent multiplication device and an imaging device expressing a high photoelectric conversion efficiency in a near-infrared light region can be achieved by using the composition according to the present embodiment.

R₁ to R₈ in the formula (3) and R₁₁ to R₁₈ in the formula (4) are each, for example, a substituent not having π-conjugated system from the viewpoint of the photoelectric conversion efficiency and may be an alkyl group as described above. The alkyl group may be a straight chain alkyl group or a branched alkyl group. The alkyl group may have 4 or more carbon atoms, such as a butyl group, a pentyl group, or a hexyl group.

When R₁ to R₈ in the formula (3) and R₁₁ to R₁₈ in the formula (4) have a substituent not having π-conjugated system, the electron clouds of HOMO and LUMO involved in photoelectric conversion can keep the distance between adjacent molecules, and thereby the movement of electric charges is easily prevented. As a result, it becomes easy to trap the electric charges, i.e., holes, in the donor material, the energy band is bent, and electrons easily flow from the electrode. Consequently, the photocurrent multiplication effect can be enhanced.

When the donor material includes a substituent roughly vertically with respect to the plane of the atomic group mainly constituting HOMO, the distance between the molecular orbital of the molecule trapping a hole and the molecular orbital of a molecule adjacent to the molecule is increased to prevent the trapped hole from moving to the adjacent molecule, and the multiplication phenomenon due to the hole trapping efficiently occurs.

In particular, in the π-conjugated system of a donor material, since the molecular orbital spreads vertically with respect to the atomic group mainly constituting HOMO, when the substituent is roughly vertical, the distance between the molecular orbital of the molecule trapping a hole and the molecular orbital of a molecule adjacent to the molecule increases vertically, which is more effective.

In the composition according to the present embodiment, the naphthalocyanine derivative represented by the formula (3) has an alkoxy group (—OR), which is an electron-donating α-position side chain, and thereby has an absorption wavelength peak in a near-infrared light region of 880 nm or more. That is, it is possible to have an absorption wavelength peak on the longer wavelength side and have a high light absorption property over a broad range of the near-infrared light region compared to naphthalocyanine derivatives not having an alkoxy group, i.e., an electron-donating α-position side chain.

In the composition according to the present embodiment, the phthalocyanine derivative represented by the formula (4) has an alkylsulfanyl group (—SR), which is an electron-donating α-position side chain, and thereby has an absorption wavelength peak in a near-infrared light region of 880 nm or more. That is, it is possible to have an absorption wavelength peak on the longer wavelength side and have a high light absorption property over a broad range of the near-infrared light region compared to phthalocyanine derivatives not having an alkylsulfanyl group, i.e., an electron-donating α-position side chain.

### Photocurrent Multiplication Device

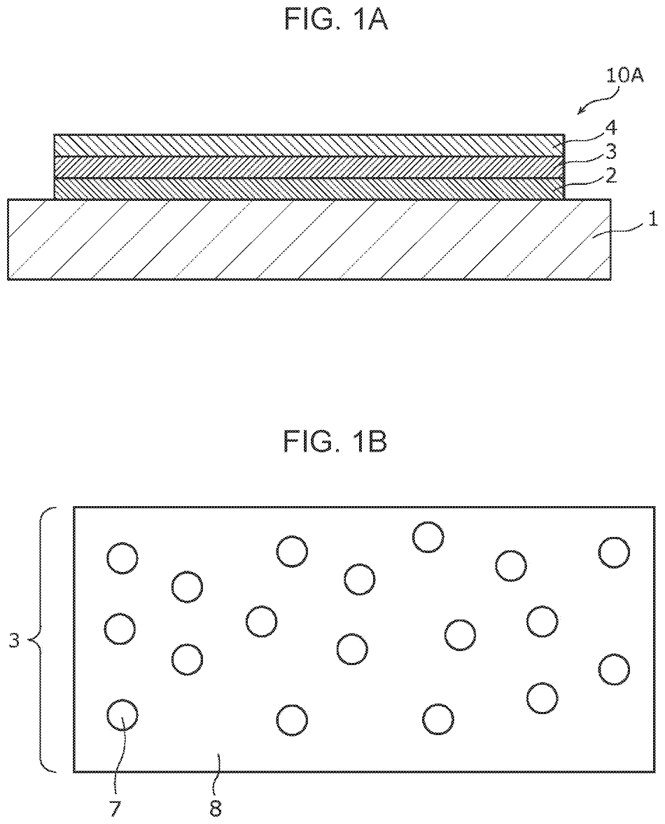

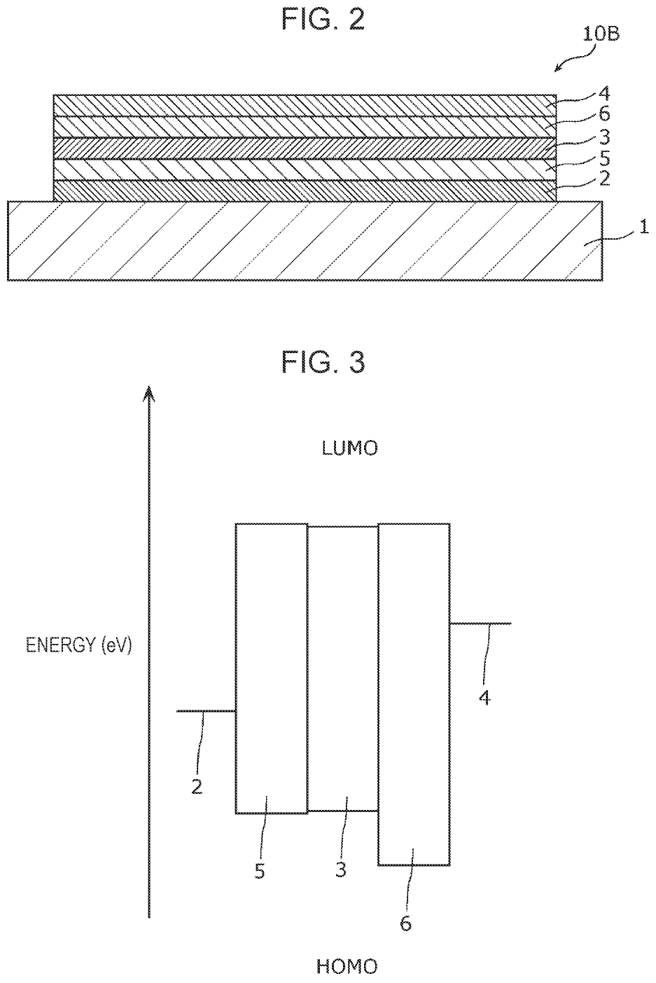

A photocurrent multiplication device utilizing a photocurrent multiplication phenomenon according to the present embodiment will now be described using FIGS. 1A, 1B, and 2. FIG. 1A is a schematic cross-sectional view of a photocurrent multiplication device 10A as an example of the photocurrent multiplication device according to the present embodiment.

The photocurrent multiplication device 10A according to the present embodiment includes a pair of electrodes, an upper electrode 4 and a lower electrode 2, arranged so as to face to each other and a photoelectric conversion film 3 disposed between the pair of electrodes and containing the above-described composition. In the present embodiment, the lower electrode 2 is an example of the first electrode, and the upper electrode 4 is an example of the second electrode.

The photocurrent multiplication device 10A is a photoconductor device that detects light utilizing a phenomenon of changing the resistance value of the photocurrent multiplication device 10A by incidence of light on the photocurrent multiplication device 10A. The photocurrent multiplication device 10A has an external quantum efficiency of 100% or more by transporting the injection electrons injected into the photoelectric conversion film 3 from the lower electrode 2 toward the upper electrode 4. The photocurrent multiplication device 10A has an external quantum efficiency of 100% or more in a wavelength region of 760 nm or more by, for example, selecting a donor material that absorbs light of a wavelength of 760 nm or more as in the composition above. In the present embodiment, a case of injecting electrons from the lower electrode 2 will be described. Incidentally, the photocurrent multiplication device 10A may have an external quantum efficiency of 100% or more by transporting injection electrons from the upper electrode 4 toward the lower electrode 2. In this case, the principle and the like will be explained by replacing the lower electrode 2 and the upper electrode 4 with each other in the description of the present embodiment. In addition, in this case, the lower electrode 2 is an example of the second electrode, and the upper electrode 4 is an example of the first electrode.

The photocurrent multiplication device 10A according to the present embodiment is supported by, for example, a supporting substrate 1.

The supporting substrate 1 is transparent to, for example, visible light and near-infrared light, and light enters the photocurrent multiplication device 10A through the supporting substrate 1. The supporting substrate 1 may be a substrate that is used in general devices including photoelectric conversion films and may be, for example, a glass substrate, a quartz substrate, a semiconductor substrate, or a plastic substrate. Incidentally, the phrase “transparent to visible light and near-infrared light” means to be substantially transparent to visible light and near-infrared light, and the transmittance of light in the visible light and near-infrared light regions may be 60% or more, 80% or more, or 90% or more.

Each component of the photocurrent multiplication device 10A according to the present embodiment will now be described.

The photoelectric conversion film 3 generates pairs of electrons and holes by photoelectric conversion. The photoelectric conversion film 3 includes, for example, a donor material and an acceptor material as the above-described composition.

The photoelectric conversion film 3 has a bulk heterojunction structure in which a p-type semiconductor as a donor material and an n-type semiconductor as an acceptor material are mixed. The photoelectric conversion film 3 traps, for example, holes in the donor material. Although details will be described later, the photoelectric conversion film 3 has a bulk heterojunction structure, the donor material traps holes, and thereby electrons injected from the lower electrode 2 easily flow. As a result, the photocurrent multiplication device 10A can carry electric charges more than the electric charges generated in the photoelectric conversion film 3 by incidence of light and shows photocurrent multiplication characteristics in which the external quantum efficiency is 100% or more. In such a configuration, the photocurrent multiplication device 10A can suppress dark current. In addition, the photoelectric conversion film 3 having the bulk heterojunction structure can suppress remaining of electric charges at the interface between the photoelectric conversion film 3 and another component, and the reliability of the photocurrent multiplication device 10A is improved. Incidentally, regarding the bulk heterojunction structure, a bulk hetero type active layer is described in detail in Japanese Patent No. 5553727.

In the bulk heterojunction structure, the donor material and the acceptor material are in contact with each other, and thereby electric charges may be generated even in a dark state. Accordingly, the dark current can be suppressed by reducing the contact between the donor material and the acceptor material. From the viewpoint of electric charge mobility, when the photoelectric conversion film 3 include a large amount of an acceptor material such as a fullerene derivative, the device resistance can be suppressed. In this case, the volume ratio and the weight ratio of the donor material to the acceptor material in the photoelectric conversion film 3 having a bulk heterojunction structure may be each 3/7 or less. The volume ratio and the weight ratio of the donor material to the acceptor material in the photoelectric conversion film 3 may be each 1/9 or less or 1/19 or less. The lower limits of the volume ratio and the weight ratio of the donor material to the acceptor material in the photoelectric conversion film 3 may be each 1/99 or more.

The bulk heterojunction structure of the photoelectric conversion film 3 may be at least partially a sea-island structure. FIG. 1B is a schematic view showing an example of the sea-island structure in the photoelectric conversion film 3. Specifically, FIG. 1B is an enlarged schematic view of a part of a cross section of the photoelectric conversion film 3. As shown in FIG. 1B, in the photoelectric conversion film 3, islands of a donor material 7 are dispersed in an acceptor material 8. That is, the photoelectric conversion film 3 at least partially has a sea-island structure in which the donor material 7 is interspersed in the photoelectric conversion film 3. When at least a part of the photoelectric conversion film 3 is of a sea-island structure including the acceptor material 8 and the donor material 7, holes as electric charges are trapped by the donor material 7 corresponding to the islands, and a photocurrent multiplication phenomenon accompanying injection of electrons which are the opposite charge of holes can be obtained. Consequently, the photocurrent multiplication device 10A can carry electric charges more than the electric charges generated in the photoelectric conversion film 3 by incidence of light, and the external quantum efficiency becomes 100% or more.

Even if the sea-island structure is present partially in the photoelectric conversion film 3, the photocurrent multiplication phenomenon can occur. However, since the electric charges are likely to accumulate with an increase in the portion of islands, substantially the whole photoelectric conversion film 3 may be a sea-island structure. In other words, the photoelectric conversion film 3 may have a structure in which the donor material 7 is dispersed in the whole photoelectric conversion film 3. The holes accumulated in the donor material 7 as the island portion of the sea-island structure are likely to uniformly disperse in the photoelectric conversion film 3. As a result, topical concentration of the electric charges can be avoided, and the reliability of the photoelectric conversion film 3 is improved.

The donor material 7 is a p-type semiconductor material. The p-type semiconductor material is, for example, a donor-type organic semiconductor material. The donor-type organic semiconductor material is mainly represented by a hole-transporting organic compound and is an organic compound having a property of easily donating electrons. In more details, the donor-type organic semiconductor material is an organic compound having a smaller ionization potential when two organic materials are brought into contact with each other. Accordingly, any organic compound that is an electron-donating organic compound can be used as the donor-type organic semiconductor material. For example, the organic semiconductor material is an organic compound having a 7C-conjugated system. As the donor-type organic semiconductor material, for example, a triarylamine compound, a benzidine compound, a pyrazoline compound, a styrylamine compound, a hydrazone compound, a triphenylmethane compound, a carbazole compound, a polysilane compound, a thiophene compound, a phthalocyanine compound, a naphthalocyanine compound, a cyanine compound, a merocyanine compound, an oxonol compound, a polyamine compound, an indole compound, a pyrrole compound, a pyrazole compound, a polyarylene compound, a condensed aromatic carbocyclic compound (a naphthalene derivative, an anthracene derivative, a phenanthrene derivative, a tetracene derivative, a pyrene derivative, a perylene derivative, or a fluoranthene derivative), or a metal complex whose ligand is a nitrogen-containing heterocyclic compound can be used. Incidentally, the donor-type organic semiconductor material is not limited to the above and, as described above, any organic compound having a smaller ionization potential than that of the organic compound used as an acceptor type semiconductor may be used as the donor-type organic semiconductor material. Thus, when the donor material 7 is an organic semiconductor material, it is possible to realize a photocurrent multiplication device 10A having spectral sensitivity characteristics at various wavelengths depending on the absorption wavelength of the organic semiconductor material.

The donor material 7 may be a phthalocyanine compound or a naphthalocyanine compound among these organic semiconductor materials. That is, the donor material 7 may have a phthalocyanine skeleton or a naphthalocyanine skeleton. Specifically, the donor material 7 may be a naphthalocyanine derivative represented by the formula (3) or a phthalocyanine derivative represented by the formula (4) mentioned in the explanation of the composition above.

The donor material 7 may include at least one substituent that does not have a 7C-conjugated system. Consequently, as described in the explanation of the composition, the electron clouds of HOMO and LUMO involved in photoelectric conversion can keep the distance between adjacent molecules, and thereby the movement of electric charges is easily prevented. The substituent may be an alkyl group having 4 or more carbon atoms. Consequently, since a substituent having a large number of carbon atoms is introduced into the donor material, the effect of easily preventing the movement of electric charges described above can be enhanced.

The donor material 7 may be a low-molecular material. Consequently, since the molecular weight of the donor material 7 is small, the donor material 7 easily moves during, for example, the formation of the photoelectric conversion film 3, and the photoelectric conversion film 3 is likely to form a sea-island structure. In addition, the dispersibility of the donor material 7 in the photoelectric conversion film 3 is improved. Incidentally, the low-molecular material is, for example, an organic compound that has a polymerization number lower than that of an oligomer and does not exhibit characteristics such as macromolecular viscoelasticity, and may be an organic compound that does not have a polymerized repeating unit.

The acceptor material 8 is, for example, an n-type semiconductor material. The n-type semiconductor material is, for example, an acceptor-type organic semiconductor material. The acceptor-type organic semiconductor material is an organic compound that mainly represented by an electron-transporting organic compound and has a property of easily accepting electrons. In more details, the acceptor-type organic semiconductor material is an organic compound having a higher electron affinity when two organic materials are used in contact with each other. Accordingly, any organic compound having an electron-accepting property can be used as the acceptor-type organic semiconductor material. Examples of the acceptor-type organic semiconductor material include fullerene, fullerene derivatives such as PCBM, condensed aromatic carbocyclic compounds (e.g., a naphthalene derivative, an anthracene derivative, a phenanthrene derivative, a tetracene derivative, a pyrene derivative, a perylene derivative, and a fluoranthene derivative), 5- to 7-membered heterocyclic compounds containing a nitrogen atom, an oxygen atom, or a sulfur atom (e.g., pyridine, pyrazine, pyrimidine, pyridazine, triazine, quinoline, quinoxaline, quinazoline, phthalazine, cinnoline, isoquinoline, pteridine, acridine, phenazine, phenanthroline, tetrazole, pyrazole, imidazole, thiazole, oxazole, indazole, benzimidazole, benzotriazole, benzoxazole, benzothiazole, carbazole, purine, triazolopyridazine, triazolopyrimidine, tetrazaindene, oxadiazole, imidazopyridine, pyrrolidine, pyrrolopyridine, thiadiazolopyridine, dibenzazepine, and tribenzazepine), polyarylene compounds, fluorene compounds, cyclopentadiene compounds, silyl compounds, and metal complexes whose ligands are nitrogen-containing heterocyclic compounds. The acceptor-type organic semiconductor material is not limited to these examples, and as described above, any organic compound having a higher electron affinity than that of the organic compound used as a donor-type organic semiconductor material may be used as the acceptor-type organic semiconductor material.

The photoelectric conversion film 3 contains, for example, a naphthalocyanine derivative represented by the formula (3) or a phthalocyanine derivative represented by the formula (4) as a donor material and fullerene or a fullerene derivative an acceptor material.

As the method for producing the photoelectric conversion film 3, for example, a coating method such as spin coating or a vacuum deposition method in which the film material is vaporized by heating under vacuum and deposited on a substrate can be used. The photoelectric conversion film 3 having a bulk heterojunction structure can be produced by application or vapor deposition of a material prepared by mixing a donor material and an acceptor material. In the spin coating, a film can be formed under the ambient atmosphere or N₂ atmosphere or the like, and the number of rotations may be 300 rpm or more and 3000 rpm or less. In addition, the solvent is evaporated after the spin coating, and baking treatment may be performed for stabilizing the film. The baking temperature may be any temperature and is, for example, 60° C. or more and 250° C. or less.

When the prevention of contamination by impurities and multi-layering for high functionality with a higher degree of freedom are considered, the vacuum deposition method may be used. The vapor deposition apparatus may be a commercially available apparatus. The temperature of the vapor deposition source during the vapor deposition is, for example, 100° C. or more and 500° C. or less and may be 150° C. or more and 400° C. or less. The degree of vacuum during the vapor deposition is, for example, 1×10⁻⁶ Pa or more and 1 Pa or less and may be 1×10⁻⁶ Pa or more and 1×10⁻⁴ Pa or less. Alternatively, a method for enhancing the deposition rate by adding metal microparticles or the like to the vapor deposition source may be used.

The blending ratio of the materials for the photoelectric conversion film 3 is shown by a weight ratio in the coating method and is shown by a volume ratio in the vacuum deposition method. More specifically, in the coating method, the blending ratio is prescribed by the weight of each material when a solution is prepared. In the vacuum deposition method, the blending ratio of each material is prescribed while monitoring the deposition film thickness of each material with a film thickness meter during the vapor deposition.

The blending ratios of materials, for example, the concentration of the donor material in the photoelectric conversion film 3 of the photocurrent multiplication device 10A or a photocurrent multiplication device 10B described later may be, for example, 30 wt % or less. Consequently, the photocurrent multiplication device 10A and the photocurrent multiplication device 10B can efficiently multiply the photocurrent and can increase the spectral sensitivity when used in an imaging device or the like. The concentration may be 10 wt % or less or 5 wt % or less.

In the present embodiment, the absorption wavelength peak of the photoelectric conversion film 3 may be 800 nm or more. Consequently, the photocurrent multiplication device according to the present embodiment can have a high light absorption property over a broad range of the near-infrared light region.

At least one of the upper electrode 4 and the lower electrode 2 is a transparent electrode made of a conducting material transparent to visible light and near-infrared light. A bias voltage is applied to the lower electrode 2 and the upper electrode 4 by wiring (not shown). For example, the polarity of the bias voltage is determined such that electrons among the electric charges generated in the photoelectric conversion film 3 move to the upper electrode 4. That is, a bias voltage is applied such that the potential of the upper electrode 4 is higher than that of the lower electrode 2. On this occasion, the holes among the electric charges generated in the photoelectric conversion film 3 remain in the photoelectric conversion film 3. Incidentally, the bias voltage may be set such that the potential of the upper electrode 4 is lower than that of the lower electrode 2 and thereby the electrons among the electric charges generated in the photoelectric conversion film 3 move to the lower electrode 2.

The bias voltage may be applied such that the value obtained by dividing the voltage value to be applied by the distance between the lower electrode 2 and the upper electrode 4, that is, the strength of the electric field occurring in the photocurrent multiplication device 10A is within a range of 1.0×10³ V/cm or more and 1.0×10⁷ V/cm or less or within a range of 1.0×10⁴ V/cm or more and 1.0×10⁷ V/cm or less. By thus adjusting the level of the bias voltage, it is possible to efficiently move the electric charges to the upper electrode 4 and the lower electrode 2, and the signals according to the electric charges can be extracted to the outside.

The materials for the lower electrode 2 and the upper electrode 4 may be transparent conducting oxides (TCOs) having a high transmittance of light in the visible light and near-infrared light regions and a small resistance value. A metal thin film of Au or the like can also be used as a transparent electrode, but in order to obtain a light transmittance of 90% or more in the visible light and near-infrared light regions, the resistance value may significantly increase compared to when a transparent electrode is produced so as to have a transmittance of 60% to 80%. Accordingly, a transparent electrode having high transparency to visible light and near-infrared light and a small resistance value can be obtained by using a TCO rather than by using a metal material such as gold (Au). The TCO is not particularly limited, and, for example, an indium tin oxide (ITO), an indium zinc oxide (IZO), an aluminum-doped zinc oxide (AZO), a fluorine-doped tin oxide (FTO), SnO₂, TiO₂, or ZnO₂ can be used. Incidentally, the lower electrode 2 and the upper electrode 4 may be produced appropriately using metal materials, such as a TCO and Au, alone or in combination of two or more thereof according to a desired transmittance.

Incidentally, the materials of the lower electrode 2 and the upper electrode 4 are not limited to the above-mentioned conducting materials transparent to visible light and near-infrared light, and other materials may be used.

The lower electrode 2 and the upper electrode 4 are produced by various methods depending on the materials to be used. For example, in the case of an ITO, a chemical reaction method such as an electron beam method, a sputtering method, a resistance heating deposition method, or a sol-gel method or a method such as application of a dispersion of indium tin oxide may be used. In such a case, after formation of an ITO film, UV-ozone treatment, plasma treatment, or the like may be further performed.

The work function of the lower electrode 2 is not particularly limited, but may be deeper by 0.6 eV or more than the LUMO energy level of the photoelectric conversion film 3 from the viewpoint of suppressing dark current while causing electron injection from the lower electrode 2 to the photoelectric conversion film 3.

According to the photocurrent multiplication device 10A, for example, photoelectric conversion is caused in the photoelectric conversion film 3 by visible light and near-infrared light incident through the supporting substrate 1 and the lower electrode 2 and/or the upper electrode 4. The holes of the pairs of electrons and holes generated by the photoelectric conversion above remain in the photoelectric conversion film 3, and the electrons are collected in the upper electrode 4. Consequently, the energy band of the photoelectric conversion film 3 is notably changed by the holes remaining in the photoelectric conversion film 3, and electron injection from the lower electrode 2 becomes possible. Accordingly, the injection charges from the lower electrode 2 flow in the photocurrent multiplication device 10A in an amount higher than the electric charges due to charge isolation in the photoelectric conversion film 3 by incidence of light. As a result, it is possible to obtain an external quantum efficiency of 100% or more.

Accordingly, for example, the light incident on the photocurrent multiplication device 10A can be detected by measuring the potential of the lower electrode 2.

In the photocurrent multiplication device 10A, the lower electrode 2 and the upper electrode 4 are in contact with the photoelectric conversion film 3. Consequently, since the lower electrode 2 and the upper electrode 4 can directly give and receive electrons with the photoelectric conversion film 3, electrons more easily flow in the photoelectric conversion film 3, and the photocurrent multiplication device 10A can improve the external quantum efficiency.

Incidentally, in the photocurrent multiplication device 10A, at least one of the lower electrode 2 and the upper electrode 4 need not be in contact with the photoelectric conversion film 3. For example, the photocurrent multiplication device 10A may further include at least one of a lower buffer layer 5 and an upper buffer layer 6 described later. By introducing at least one of the lower buffer layer 5 and the upper buffer layer 6, an unnecessary flow of electric charges during the dark time can be suppressed to suppress dark current. In addition, the lower buffer layer 5 and the upper buffer layer 6 may have a function of suppressing the heat transfer to the photoelectric conversion film 3 and improving the heat resistance of the photocurrent multiplication device 10A. Incidentally, the details of the lower buffer layer 5 and the upper buffer layer 6 will be described later.

Then, another example of the photocurrent multiplication device according to the present embodiment will be described using FIGS. 2 and 3. FIG. 2 is a schematic cross-sectional view of a photocurrent multiplication device 10B, another example of the photocurrent multiplication device. FIG. 3 shows an example of the energy band diagram of the photocurrent multiplication device 10B. Incidentally, in the photocurrent multiplication device 10B shown in FIG. 2, the component that is the same as that of the photocurrent multiplication device 10A shown in FIG. 1A is denoted by the same reference sign. In FIG. 3, the LUMO energy level of the photoelectric conversion film 3 is the LUMO energy level of the acceptor material 8, and the HOMO energy level of the photoelectric conversion film 3 is the HOMO energy level of the donor material 7.

As shown in FIG. 2, the photocurrent multiplication device 10B includes a lower electrode 2, an upper electrode 4, and a photoelectric conversion film 3 disposed between the lower electrode 2 and the upper electrode 4.

The photocurrent multiplication device 10B includes a lower buffer layer 5 disposed between the lower electrode 2 and the photoelectric conversion film 3, and an upper buffer layer 6 disposed between the upper electrode 4 and the photoelectric conversion film 3. The lower buffer layer 5 and the upper buffer layer 6 are examples of the buffer layer. Incidentally, the lower electrode 2, the photoelectric conversion film 3, and the upper electrode 4 are as described above in the photocurrent multiplication device 10A, and therefore the description thereof is omitted here.

The lower buffer layer 5 is provided for reducing the dark current due to injection of electrons from, for example, the lower electrode 2 and suppresses the injection of electrons from the lower electrode 2 into the photoelectric conversion film 3 during the dark time. In contrast, in the photocurrent multiplication device utilizing a photocurrent multiplication phenomenon, since the photocurrent multiplication phenomenon is caused by electron injection from the lower electrode 2 during the photoelectric conversion, it is desirable that the lower buffer layer 5 does not prevent the electron injection from an electrode during the bright time.

Accordingly, efficient electric charge injection can be easily caused when an electric field (i.e., bias voltage) is applied during the bright time by, for example, expressing a tunnel effect through a reduction in the thickness of the lower buffer layer 5 in order to efficiently inject electric charges from the lower electrode 2. The thickness of the lower buffer layer 5 is not particularly limited, but is, for example, 20 nm or less from the viewpoint of improving the electric charge injection efficiency and may be 10 nm or less. The difference between the LUMO energy level of the lower buffer layer 5 and the LUMO energy level of the photoelectric conversion film 3 (specifically, acceptor material 8) may be 0.5 eV or less. Consequently, the increase in dark current can also be suppressed while suppressing obstruction to the electron injection during the photocurrent multiplication phenomenon.

As the material for the lower buffer layer 5, the above-mentioned p-type semiconductor material, n-type semiconductor material, or hole-transporting organic compound can be used.

The upper buffer layer 6 is provided, for example, for reducing the dark current due to injection of holes from the upper electrode 4 and suppresses injection of holes from the upper electrode 4 into the photoelectric conversion film 3. The HOMO energy level of the upper buffer layer 6 may be deeper than the HOMO energy level of the photoelectric conversion film 3, for example, from the viewpoint of suppressing the movement of holes in the upper electrode 4 and the photoelectric conversion film 3 through the upper buffer layer 6.

As the material for the upper buffer layer 6, for example, an organic substance such as copper phthalocyanine, PTCDA (3,4,9,10-perylenetetracarboxylic dianhydride), an acetylacetonate ligand, BCP (bathocuproine), Alq (tris(8-quinolinolate)aluminum), fullerene C60, or a fullerene derivative such as PCBM, or an organometallic compound, or an inorganic substance such as MgAg or MgO can be used. In addition, as the material for the upper buffer layer 6, the above-mentioned n-type semiconductor or electron-transporting organic compound can also be used.

The upper buffer layer 6 may have a high transmittance of visible light and near-infrared light in order not to prevent the light absorption of the photoelectric conversion film 3. The upper buffer layer 6 may have a light transmittance of 60% or more, 80% or more, or 90% or more in the visible light and near-infrared light regions. In addition, from the viewpoint of increasing the transmittance of visible light and near-infrared light, the thickness of the upper buffer layer 6 may be reduced. The thickness of the upper buffer layer 6 depends on the configuration of the photoelectric conversion film 3, the thickness of the upper electrode 4, and so on, but may be, for example, 2 nm or more and 50 nm or less.

When the lower buffer layer 5 is provided, the material for the lower electrode 2 is selected from the above-mentioned materials considering the adhesion with the lower buffer layer 5, electron affinity, ionization potential, stability, and so on. Incidentally, the same also applies to the upper electrode 4 when the upper buffer layer 6 is provided.

As shown in FIG. 3, when the work function of the upper electrode 4 is relatively deep (for example, the difference from the vacuum level is 4.8 eV or more), the barrier lowers when holes moves to the photoelectric conversion film 3 during the application of a bias voltage. Accordingly, injection of holes from the upper electrode 4 into the photoelectric conversion film 3 is likely to occur, resulting in a risk of an increase in the dark current. The photocurrent multiplication device 10B can suppress the dark current by including the upper buffer layer 6.

Incidentally, the photocurrent multiplication device 10B may include only one of the lower buffer layer 5 and the upper buffer layer 6. For example, the photocurrent multiplication device 10B may have a configuration in which the lower buffer layer 5 is not disposed and the upper buffer layer 6 is disposed.

### Imaging Device

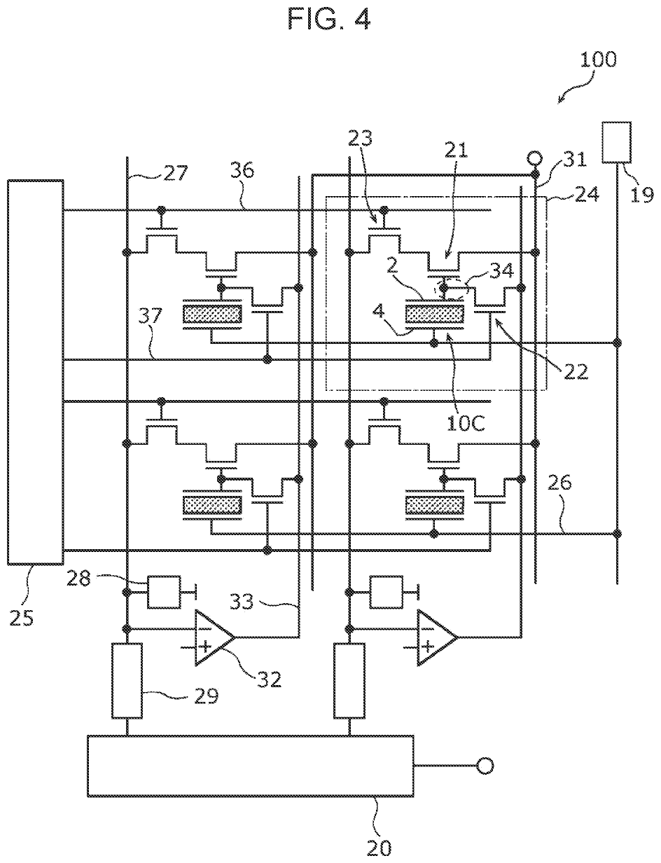

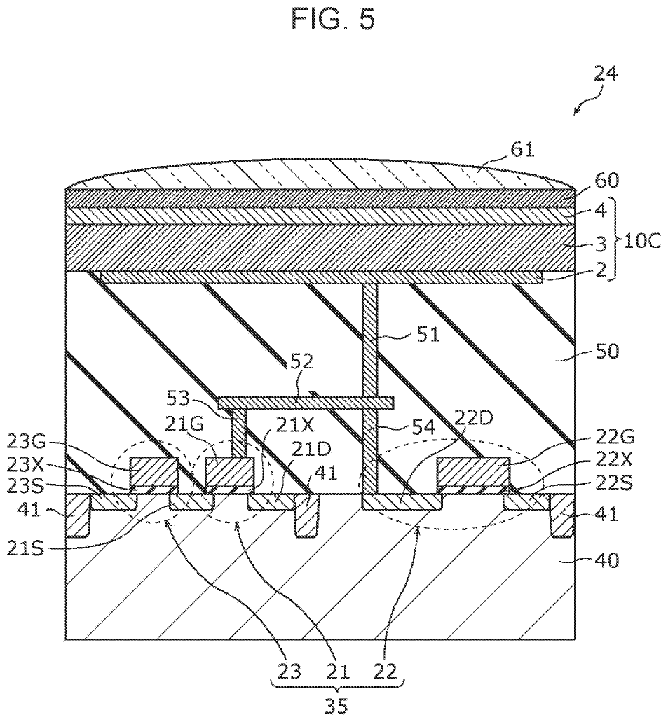

An imaging device according to the present embodiment will now be described using FIGS. 4 and 5. FIG. 4 is a diagram showing an example of the circuit constitution of the imaging device 100 according to the present embodiment. FIG. 5 is a schematic cross-sectional view showing an example of the device structure of a pixel 24 in the imaging device 100 according to the present embodiment.

As shown in FIGS. 4 and 5, the imaging device 100 according to the present embodiment includes a semiconductor substrate 40 as an example of the substrate, an electric charge detection circuit 35 provided in the semiconductor substrate 40, a photoelectric converter 10C provided on the semiconductor substrate 40, and a pixel 24 including an electric charge storage node 34 electrically connected to the electric charge detection circuit 35 and the photoelectric converter 10C. The photoelectric converter 10C of the pixel 24 includes, for example, the above-described photocurrent multiplication device 10A or photocurrent multiplication device 10B. The electric charge storage node 34 accumulates electric charges obtained in the photoelectric converter 10C, and the electric charge detection circuit 35 detects the electric charges accumulated in the electric charge storage node 34. Incidentally, the electric charge detection circuit 35 provided in the semiconductor substrate 40 may be provided on the semiconductor substrate 40 or may be directly provided in the semiconductor substrate 40.

As shown in FIG. 4, the imaging device 100 includes a plurality of pixels 24 and peripheral circuits such as a vertical scanning circuit 25 and a horizontal signal reading circuit 20. The imaging device 100 is, for example, an organic image sensor realized by a one-chip integrated circuit and includes a pixel array including a plurality of two-dimensionally arrayed pixels 24.

The plurality of pixels 24 is arranged two-dimensionally, i.e., in the row direction and the column direction, on the semiconductor substrate 40 and form a photosensitive area. The “photosensitive area” is also referred to as “pixel area”. FIG. 4 shows an example in which pixels 24 are arranged in a matrix of two rows and two columns. Incidentally, in FIG. 4, for convenience of illustration, a circuit for setting the sensitivity of the pixels 24 individually (for example, pixel electrode control circuit) is omitted. The imaging device 100 may be a line sensor. In such a case, a plurality of pixels 24 may be arranged one-dimensionally. Incidentally, the row direction and the column direction refer to the directions in which the row and the column extend, respectively. That is, in FIG. 4, the vertical direction on the paper is the column direction, and the horizontal direction is the row direction.

As shown in FIGS. 4 and 5, each pixel 24 includes the photoelectric converter 10C, the electric charge detection circuit 35, and the electric charge storage node 34 electrically connected to the both. The electric charge detection circuit 35 includes an amplification transistor 21, a reset transistor 22, and an address transistor 23.

The photoelectric converter 10C includes a lower electrode 2 provided as a pixel electrode and an upper electrode 4 provided as a counter electrode facing the pixel electrode. As the photoelectric converter 10C, the photocurrent multiplication device 10A or 10B described above may be used. The upper electrode 4 is applied with a predetermined bias voltage through a counter electrode signal line 26.

The lower electrode 2 is a pixel electrode provided to each of the pixels 24, and the plurality of the lower electrodes 2 is arranged in an array. The lower electrode 2 is connected to the gate electrode of the amplification transistor 21, and the signal electric charges collected by the lower electrode 2 are accumulated in the electric charge storage node 34 located between the lower electrode 2 and the gate electrode of the amplification transistor 21. In the present embodiment, the signal electric charge is a hole, but the signal electric charge may be an electron.

The signal electric charges accumulated in the electric charge storage node 34 are applied to the gate electrode of the amplification transistor 21 as a voltage according to the amount of the signal electric charges. The amplification transistor 21 amplifies this voltage, which is selectively read as a signal voltage by the address transistor 23. The reset transistor 22 is connected to the lower electrode 2 through the source/drain electrode and resets the signal electric charges accumulated in the electric charge storage node 34. In other words, the reset transistor 22 resets the potentials of the gate electrode of the amplification transistor 21 and the lower electrode 2.

In order to perform the above-described operation selectively in the plurality of pixels 24, the imaging device 100 includes power supply wiring 31, a vertical signal line 27, an address signal line 36, and a reset signal line 37, and these lines are respectively connected to each of the pixels 24. Specifically, the power supply wiring 31 is connected to the source/drain electrode of the amplification transistor 21, and the vertical signal line 27 is connected to the source/drain electrode of the address transistor 23. The address signal line 36 is connected to the gate electrode of the address transistor 23. The reset signal line 37 is connected to the gate electrode of the reset transistor 22.

The peripheral circuits include a voltage supply circuit 19, a vertical scanning circuit 25, a horizontal signal reading circuit 20, a plurality of column signal processing circuits 29, a plurality of load circuits 28, and a plurality of differential amplifiers 32. The vertical scanning circuit 25 is also referred to as a row scanning circuit. The horizontal signal reading circuit 20 is also referred to as a column scanning circuit. The column signal processing circuit 29 is also referred to as a row signal storage circuit. The differential amplifier 32 is also referred to as a feedback amplifier.

The voltage supply circuit 19 is electrically connected to the upper electrode 4 through the counter electrode signal line 26. The voltage supply circuit 19 gives a potential difference between the upper electrode 4 and the lower electrode 2 by applying a voltage to the upper electrode 4. For example, in the photocurrent multiplication device 10A, when a voltage higher than the voltage of the lower electrode 2 is applied to the upper electrode 4, electrons are injected from the lower electrode 2 into the photoelectric conversion film 3. That is, the voltage supply circuit 19 applies a bias voltage to the upper electrode 4 for injecting electrons into the lower electrode 2.

The vertical scanning circuit 25 is connected to the address signal line 36 and the reset signal line 37, selects a plurality of the pixels 24 arranged in each row on a row-by-row basis, and performs reading of the signal voltage and resetting of the potential of the lower electrode 2. The power supply wiring 31 functioning as a source follower power supply supplies a predetermined power supply voltage to each pixel 24. The horizontal signal reading circuit 20 is electrically connected to a plurality of column signal processing circuits 29. The column signal processing circuits 29 are electrically connected to the pixels 24 arranged in the respective columns through the vertical signal lines 27 corresponding to the respective columns. The load circuits 28 are electrically connected to the respective vertical signal lines 27. The load circuit 28 and the amplification transistor 21 form a source follower circuit.

The plurality of differential amplifiers 32 are provided so as to correspond to the respective columns. The input terminal on the negative side of the differential amplifier 32 is connected to the corresponding vertical signal line 27. The output terminal of the differential amplifier 32 is connected to the pixel 24 through a feedback line 33 corresponding to each column.

The vertical scanning circuit 25 applies a row selection signal that controls ON and OFF of the address transistor 23 to the gate electrode of the address transistor 23 by the address signal line 36. Consequently, the row to be read is scanned and selected. The signal voltage is read from the pixels 24 in the selected row into the vertical signal line 27. The vertical scanning circuit 25 applies a reset signal that controls ON and OFF of the reset transistor 22 to the gate electrode of the reset transistor 22 through the reset signal line 37. Consequently, the row of pixels 24 to be reset is selected. The vertical signal line 27 transmits the signal voltage read from the pixels 24 selected by the vertical scanning circuit 25 to the column signal processing circuit 29.

The column signal processing circuit 29 performs noise suppression signal processing represented by correlated double sampling, analog-digital conversion (AD conversion), and so on.

The horizontal signal reading circuit 20 sequentially reads signals from a plurality of column signal processing circuits 29 to a horizontal common signal line (not shown).

The differential amplifier 32 is connected to the drain electrode of the reset transistor 22 through the feedback line 33. Accordingly, the differential amplifier 32 receives an output value of the address transistor 23 in the negative terminal when the address transistor 23 and the reset transistor 22 are in a conduction state. The differential amplifier 32 performs feedback operation such that the gate potential of the amplification transistor 21 is a predetermined feedback voltage. On this occasion, the output voltage value of the differential amplifier 32 is 0 V or a positive voltage near 0 V. The feedback voltage means an output voltage of the differential amplifier 32.

As shown in FIG. 5, the pixel 24 includes a semiconductor substrate 40, an electric charge detection circuit 35, a photoelectric converter 10C, and an electric charge storage node 34 (see FIG. 4).

The semiconductor substrate 40 may be an insulative substrate provided with a semiconductor layer on the surface on the side where the photosensitive area is formed, for example, a p-type silicon substrate. The semiconductor substrate 40 has impurity areas 21D, 21S, 22D, 22S, and 23S and a device isolation region 41 for electrical separation between pixels 24. The impurity areas 21D, 21S, 22D, 22S, and 23S are, for example, n-type areas. Here, the device isolation region 41 is also provided between the impurity area 21D and the impurity area 22D. Consequently, the signal electric charges accumulated in the electric charge storage node 34 are prevented from leaking. Incidentally, the device isolation region 41 is formed by, for example, acceptor ion implantation under predetermined implantation conditions.

The impurity areas 21D, 21S, 22D, 22S, and 23S are, for example, diffusion layers formed in the semiconductor substrate 40. As shown in FIG. 5, the amplification transistor 21 includes impurity areas 21S and 21D and a gate electrode 21G. The impurity areas 21S and 21D function as, for example, the source region and the drain region, respectively, of the amplification transistor 21. A channel region of the amplification transistor 21 is formed between the impurity areas 21S and 21D.

Similarly, the address transistor 23 includes impurity areas 23S and 21S and a gate electrode 23G connected to the address signal line 36. In this example, the amplification transistor 21 and the address transistor 23 share the impurity area 21S and are thereby electrically connected to each other. The impurity area 23S functions as, for example, a source region of the address transistor 23. The impurity area 23S is connected to the vertical signal line 27 shown in FIG. 4.

The reset transistor 22 includes the impurity areas 22D and 22S and a gate electrode 22G connected to the reset signal line 37. The impurity area 22S functions as, for example, a source region of the reset transistor 22. The impurity area 22S is connected to the reset signal line 37 shown in FIG. 4.

An interlayer insulating layer 50 is stacked on the semiconductor substrate 40 so as to cover the amplification transistor 21, the address transistor 23, and the reset transistor 22.

In the interlayer insulating layer 50, a wiring layer (not shown in FIG. 5) can be arranged. The wiring layer is formed from, for example, a metal such as copper and can partially include the above-described wiring such as the vertical signal line 27. The number of insulating layers in the interlayer insulating layer 50 and the number of wiring layers arranged in the interlayer insulating layer 50 can be arbitrarily set.

In the interlayer insulating layer 50, a contact plug 54 connected to the impurity area 22D of the reset transistor 22, a contact plug 53 connected to the gate electrode 21G of the amplification transistor 21, a contact plug 51 connected to the lower electrode 2, and wiring 52 connecting the contact plug 51, the contact plug 54, and the contact plug 53 are arranged. Consequently, the impurity area 22D functioning as the drain electrode of the reset transistor 22 is electrically connected to the gate electrode 21G of the amplification transistor 21.

The electric charge detection circuit 35 detects the signal electric charges captured by the lower electrode 2 and outputs a signal voltage. The electric charge detection circuit 35 includes the amplification transistor 21, the reset transistor 22, and the address transistor 23 and is formed in the semiconductor substrate 40.

The amplification transistor 21 is formed in the semiconductor substrate 40 and includes impurity areas 21D and 21S that function as a drain electrode and a source electrode, respectively, and a gate insulating layer 21X formed on the semiconductor substrate 40, and a gate electrode 21G formed on the gate insulating layer 21X.

The reset transistor 22 is formed in the semiconductor substrate 40 and includes impurity areas 22D and 22S that function as a drain electrode and a source electrode, respectively, a gate insulating layer 22X formed on the semiconductor substrate 40, and a gate electrode 22G formed on the gate insulating layer 22X.

The address transistor 23 is formed in the semiconductor substrate 40 and includes impurity areas 21S and 23S that function as a drain electrode and a source electrode, respectively, a gate insulating layer 23X formed on the semiconductor substrate 40, and a gate electrode 23G formed on the gate insulating layer 23X. The impurity area 21S is shared by the amplification transistor 21 and the address transistor 23. Consequently, the amplification transistor 21 and the address transistor 23 are connected in series.

The above-described photoelectric converter 10C is arranged on the interlayer insulating layer 50. In other words, in the present embodiment, a plurality of pixels 24 constituting a pixel array is formed on the semiconductor substrate 40. The plurality of pixels 24 two-dimensionally arranged on the semiconductor substrate 40 forms a photosensitive area. The distance between two adjacent pixels 24 (i.e., pixel pitch) may be, for example, about 2 μm.

The photoelectric converter 10C has a structure of the above-described photocurrent multiplication device 10A or photocurrent multiplication device 10B.

A color filter 60 is provided above the photoelectric converter 10C, and a microlens 61 is provided thereabove. The color filter 60 is formed as, for example, an on-chip color filter by patterning. As the material for the color filter 60, for example, a photosensitive resin in which a dye or pigment is dispersed is used. The microlens 61 is provided as, for example, an on-chip microlens. As the microlens 61, for example, an ultraviolet sensitive material is used.

The imaging device 100 can be manufactured using a general semiconductor manufacturing process. In particular, when a silicon substrate is used as the semiconductor substrate 40, various silicon semiconductor processes can be used for the manufacturing.

As described above, according to the present embodiment, a photocurrent multiplication device and an imaging device with a high photoelectric conversion efficiency can be realized by using a photoelectric conversion film that includes a composition as a donor material and can reduce dark current.

### EXAMPLES

The composition and the photocurrent multiplication device according to the present disclosure will now be described specifically using examples, but the present disclosure is not limited only to the following examples.

Hereinafter, a butyl group C₄H₉, a pentyl group C₅H₁₁, and a hexyl group C₆H₁₃ may be represented by Bu, Pent, and Hex, respectively, and a naphthalocyanine skeleton C₄₈H₂₆N₈ and a phthalocyanine skeleton C₃₂H₁₈N₈ may be represented by Nc and Pc, respectively.

### Naphthalocyanine Derivative

A naphthalocyanine derivative included in a composition according to the present disclosure will now be more specifically described by showing Example 1.

### Example 1

Synthesis of (OBu)₈Si(OSiHex₃)₂Nc

A compound (OBu)₈Si(OSiHex₃)₂Nc represented by the following structural formula (A-3) was synthesized according to the steps (1) and (2) described below.

Step (1) Synthesis of (OBu)₈Si(OH)₂Nc (Structural Formula (A-2))

This synthesis was studied with reference to MOHAMED AOUDIA et. al., “Synthesis of a Series of Octabutoxy- and Octabutoxybenzophthalocyanines and Photophysical Properties of Two Members of the Series”, Journal of American Chemical Society, American Chemical Society, 1997, Vol. 119, No. 26, pp. 6029-6039 (Non-Patent Literature 3).

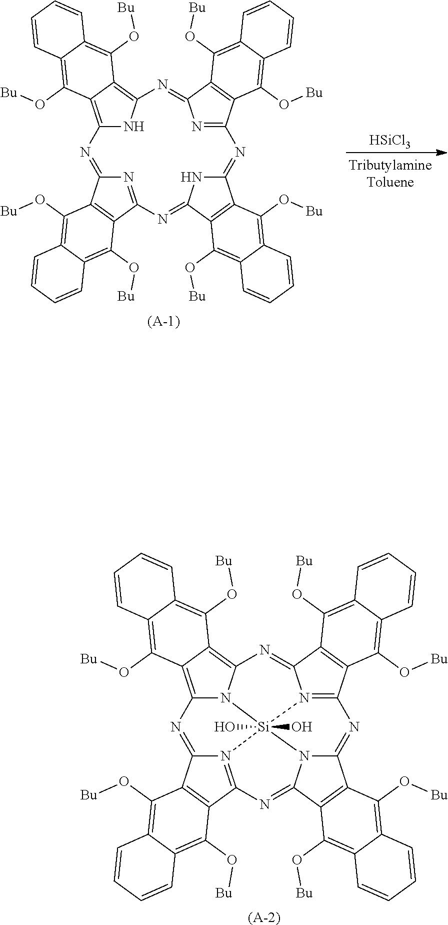

In a 1000-mL reaction vessel purged with argon, 0.95 g of (OBu)₈H₂Nc represented by the structural formula (A-1), 92 mL of tributylamine, and 550 mL of dehydrated toluene were placed, and 3.7 mL of HSiCl₃ was further added thereto, followed by heating and stirring at 80° C. for 24 hours. Subsequently, the reaction liquid was allowed to cool to room temperature, and 3.7 mL of HSiCl₃ was added to the reaction liquid, followed by heating and stirring at 80° C. for 24 hours. Subsequently, the reaction liquid was allowed to cool to room temperature, and 1.9 mL of HSiCl₃ was added to the reaction liquid, followed by heating and stirring at 80° C. for 24 hours.

The reaction liquid was allowed to cool to room temperature, and 360 mL of distilled water was added to the reaction liquid, followed by stirring for 1 hour. To the reaction liquid, 180 mL of triethylamine was added, followed by extraction with 100 mL of toluene four times. The extracted organic layer was washed with distilled water, and the organic layer was concentrated to obtain 1.54 g of a crude composition. This was purified by neutral alumina column chromatography to give a target compound (OBu)₈Si(OH)₂Nc represented by the structural formula (A-2) as a brown solid. The amount of the target compound was 0.53 g, and the yield of the target compound was 50%.

Step (2) Synthesis of (OBu)₈Si(OSiHex₃)₂Nc

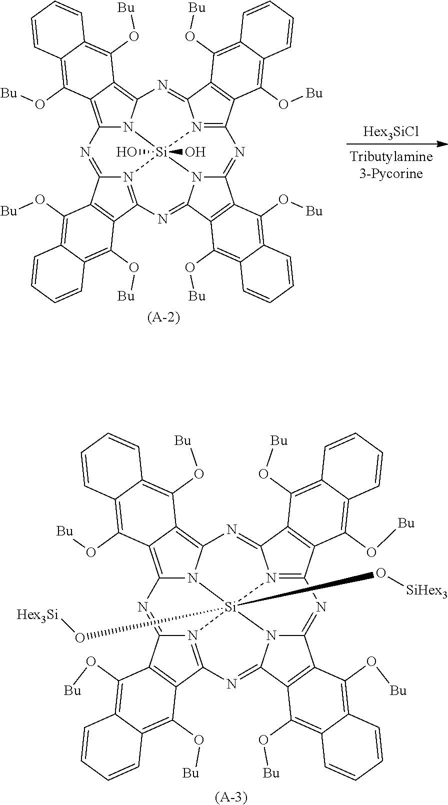

In a 200-mL reaction vessel purged with argon, 1.195 g of (OBu)₈Si(OH)₂Nc represented by the structural formula (A-2) synthesized in the step (1), 2.14 mL of trihexylsilyl chloride, and 3.8 g of tributylamine were placed and were dissolved in 60 mL of 3-picoline, followed by heating and stirring at 115° C. for 14 hours. The reaction liquid was cooled to room temperature, and 100 mL of water was then added to the reaction liquid, and 100 mL of methanol was further added thereto to precipitate a solid component. The precipitated solid component was collected by filtration. The filtrated solid component was purified by neutral alumina column chromatography using only heptane as the eluent, followed by concentration for solidification. The purified solid component was further suspended and washed by methanol, and the resulting solid component was dried under reduced pressure at 85° C. for 12 hours to give a target compound (OBu)₈Si(OSiHex₃)₂Nc represented by the structural formula (A-3). The amount of the target compound was 1.34 g, and the yield of the target compound was 79%.

The resulting target compound was identified by ¹H-NMR (proton nuclear magnetic resonance spectrometry) and MALDI-TOF-MS (matrix-assisted laser desorption ionization time-of-flight mass spectrometry). The results are as follows:

¹H-NMR (300 MHz, CDCl₃): δ (ppm)=8.99 (8H), 7.87 (8H), 5.21 (16H), 2.24 (16H), 1.65 (16H), 1.05 (24H), 0.42 (12H), 0.17 (42H), −0.72 (12H), −1.78 (12H); and

MALDI-TOF-MS measured value: m/z=1916.88 (M⁺).

The chemical formula of the target compound is C₁₁₆H₁₆₆N₈O₁₀Si₃, and the exact mass is 1915.20.

From the results above, it was confirmed that the target compound was obtained by the above-described synthesis procedure.

The absorption spectrum of a film formed by applying a chloroform solution of the (OBu)₈Si(OH)₂Nc synthesized above onto a quartz substrate was measured. As a result, the (OBu)₈Si(OH)₂Nc had absorption peaks at 470 nm, 502 nm, 776 nm, and 888 nm, and the wavelength of the maximum peak of the (OBu)₈Si(OH)₂Nc was 888 nm.

### Phthalocyanine Derivative

A phthalocyanine derivative included in a composition according to the present disclosure will now be more specifically described by showing Example 2.

### Example 2

Synthesis of (SPent)₈Si(OPh-3,5-(COOMe)₂)₂Pc

A compound (SPent)₈Si(OPh-3,5-(COOMe)₂)₂Pc represented by the following structural formula (A-5) was synthesized according to the step (3) described below.

Step (3) Synthesis of (SPent)₈Si(OPh-3,5-(COOMe)₂)₂Pc

(SPent)₈Si(OH)₂Pc represented by the structural formula (A-4) as a starting material was synthesized by the same procedure as that described in Example of Japanese Unexamined Patent Application Publication No. 2019-176126.

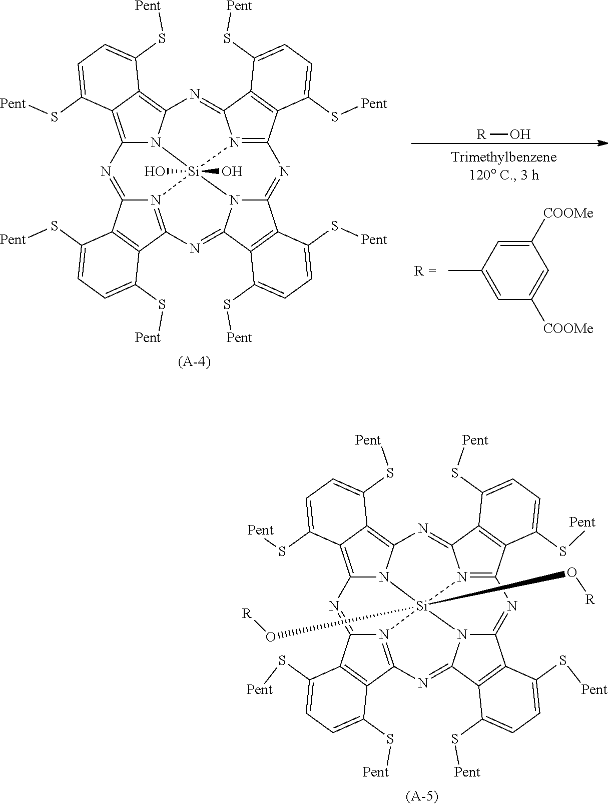

In an argon atmosphere, 0.33 g of (SPent)₈Si(OH)₂Pc represented by the structural formula (A-4) was dissolved in 21 mL of 1,2,4-trimethylbenzene, and 2.6 g of dimethyl 4-hydroxyisophthalate was added thereto, followed by heating and stirring at 120° C. for 3 hours. After confirmation of completion of the reaction by TLC (thin-layer chromatography), the solid was precipitated with methanol, and the precipitated solid component was collected by filtration. The filtrated solid component was washed with methanol and was then dried under reduced pressure at 100° C. for 3 hours to give a target compound (SPent)₈Si(OPh-3,5-(COOMe)₂)₂Pc represented by the structural formula (A-5) as a dark violet powder. The amount of the target compound was 229 mg, and the yield of the target compound was 80%.

The resulting target compound was identified by ¹H-NMR and MALDI-TOF-MS.

The results are as follows:

¹H-NMR (400 MHz, CDCl₃): δ (ppm)=7.57 (2H), 7.52 (8H), 4.18 (4H), 3.13 (28H), 1.94 (16H), 1.53 (16H), 1.36 (16H), 0.93 (24H); and

MALDI-TOF-MS measured value: m/z=1775.83 (M⁻).

The chemical formula of the target compound was C₉₂H₁₁₄N₈O₁₀S₈Si, and the exact mass was 1774.62.

From the results above, it was confirmed that the target compound was obtained by the above-described synthesis procedure.

The (SPent)₈Si(OPh-3,5-(COOMe)₂)₂Pc synthesized above was dissolved in tetrahydrofuran, and the absorption spectrum was measured. As a result, the (SPent)₈Si(OPh-3,5-(COOMe)₂)₂Pc had absorption peaks at 360 nm, 752 nm, and 851 nm, and the wavelength of the maximum peak of the (SPent)₈Si(OPh-3,5-(COOMe)₂)₂Pc was 851 nm.

### Photoelectric Conversion Film

The photoelectric conversion films according to the present disclosure will now be described more specifically by showing Examples 3 to 8.

### Example 3

### Production of Photoelectric Conversion Film

Quartz glass having a thickness of 0.7 mm was used as a supporting substrate, and the (OBu)₈Si(OSiHex₃)₂Nc obtained in Example 1 as a donor material and fullerene C60 as an acceptor material were vapor deposited thereon in a volume ratio of 1:30 to give a photoelectric conversion film having a thickness of 325 nm and an ionization potential of 5.2 eV.

### Measurement of Absorption Spectrum

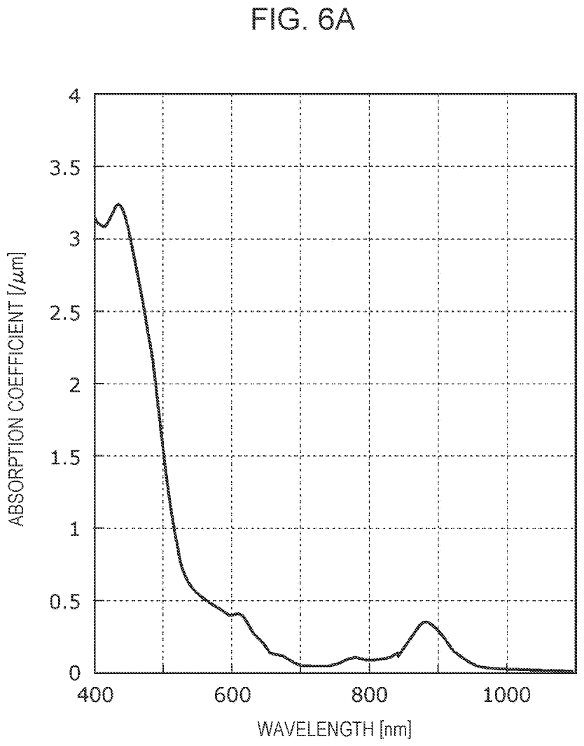

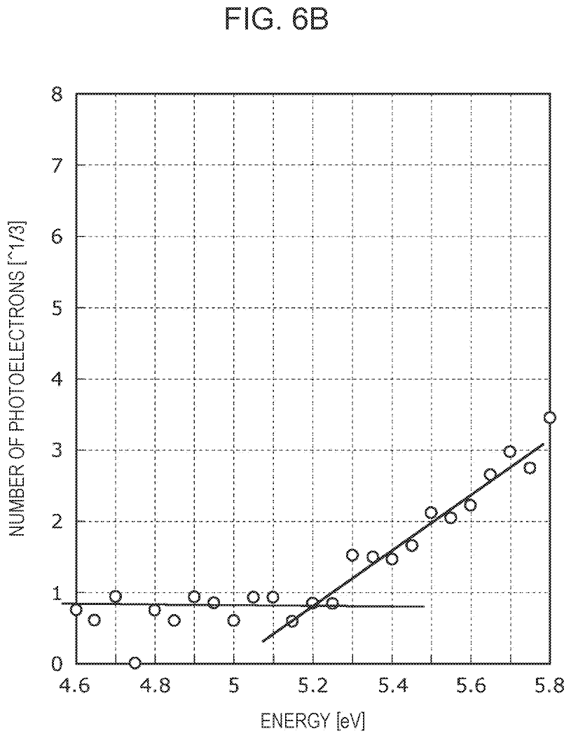

The absorption spectrum of the resulting photoelectric conversion film was measured. In the measurement, a spectrophotometer (manufactured by Hitachi High-Technologies Corporation, U4100) was used. The measurement wavelength region of the absorption spectrum was from 400 nm to 1100 nm. The measurement results are shown in FIG. 6A.

As shown in FIG. 6A, in the photoelectric conversion film of Example 3, an absorption peak was observed near 884 nm.

### Measurement of Ionization Potential

Regarding the photoelectric conversion film obtained in Example 3, the ionization potential, which is the difference between the vacuum level and the HOMO energy level, was measured. In the measurement of the ionization potential, a film of the compound obtained in Example 1 was formed on an ITO substrate, and the measurement was performed using an atmospheric photoelectron spectrometer (manufactured by RIKEN KEIKI Co., Ltd., AC-3). The measurement results are shown in FIG. 6B.

In the measurement of ionization potential, the number of photoelectrons when the energy of ultraviolet light irradiation is changed is detected. Accordingly, the energy position at which photoelectrons begin to be detected can be defined as the ionization potential. In FIG. 6B, the intersection of two straight lines is the energy position at which photoelectrons begin to be detected.

### Example 4

Quartz glass having a thickness of 0.7 mm was used as a supporting substrate, and a chloroform solution of a mixture of the (SPent)₈Si(OPh-3,5-(COOMe)₂)₂Pc obtained in Example 2 as a donor material and a PCBM derivative as an acceptor material in a weight ratio of 1:9 was applied thereon by a spin coating method to give a photoelectric conversion film having a thickness of 211 nm and an ionization potential of 5.2 eV.

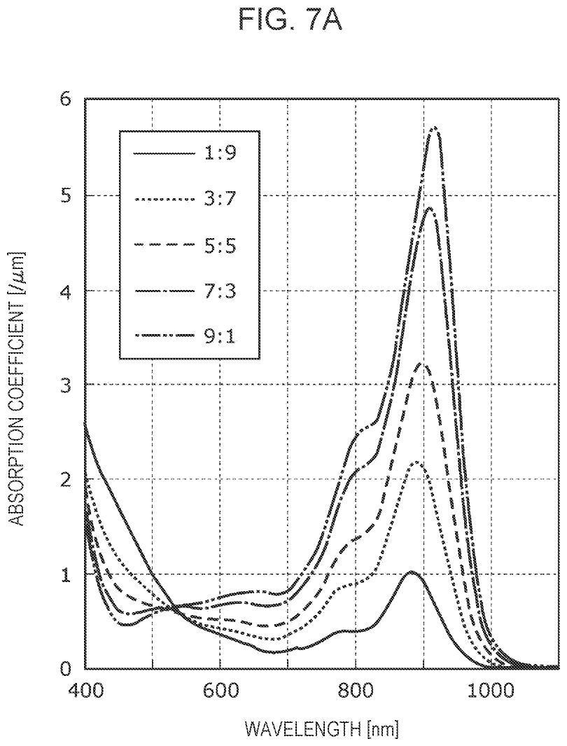

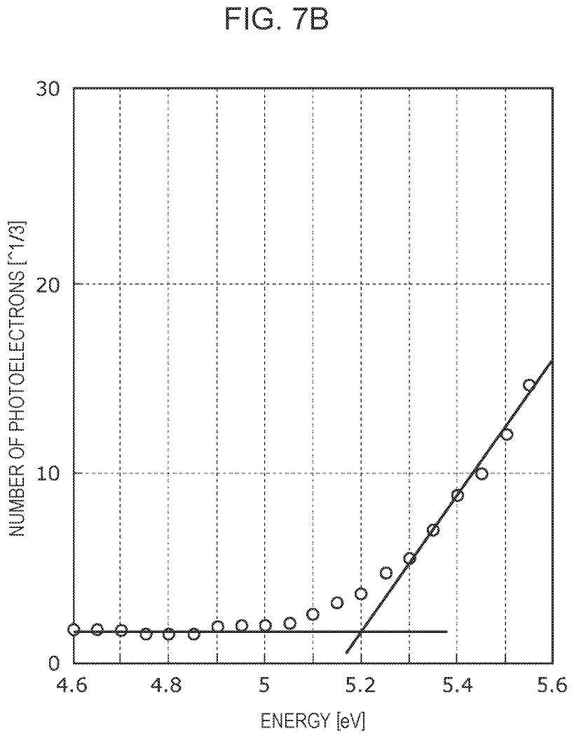

The absorption spectrum of the resulting photoelectric conversion film was measured by the same method as in Example 3. The measurement results are shown by the solid line graph in FIG. 7A. The ratios shown by the legend in FIG. 7A are the weight ratios of (SPent)₈Si(OPh-3,5-(COOMe)₂)₂Pc and a PCBM derivative corresponding to Examples 4 and 8. The ionization potential was measured by the same method as in Example 3 except that the compound obtained in Example 2 was used. The measurement results are shown in FIG. 7B. Incidentally, although the measurement results of ionization potential in the following Examples 5 to 8 are not shown in the drawing, the photoelectric conversion films were the same as in Example 4 except that the weight ratios of the (SPent)₈Si(OPh-3,5-(COOMe)₂)₂Pc and the PCBM derivative was changed from that in Example 4, the values of the ionization potential were the same as that in Example 4.

As shown by the solid line graph in FIG. 7A, in the photoelectric conversion film of Example 7, an absorption peak was observed near 884 nm.

### Example 5

Quartz glass having a thickness of 0.7 mm was used as a supporting substrate, and a chloroform solution of a mixture of the (SPent)₈Si(OPh-3,5-(COOMe)₂)₂Pc obtained in Example 2 and a PCBM derivative in a weight ratio of 3:7 was applied thereon by a spin coating method to give a photoelectric conversion film having a thickness of 233 nm.

The absorption spectrum of the resulting photoelectric conversion film was measured by the same method as in Example 3. The measurement results are shown by the dotted line graph in FIG. 7A.

As shown by the dotted line graph in FIG. 7A, in the photoelectric conversion film of Example 5, an absorption peak was observed near 888 nm.

### Example 6

Quartz glass having a thickness of 0.7 mm was used as a supporting substrate, and a chloroform solution of a mixture of the (SPent)₈Si(OPh-3,5-(COOMe)₂)₂Pc obtained in Example 2 and a PCBM derivative in a weight ratio of 5:5 was applied thereon by a spin coating method to give a photoelectric conversion film having a thickness of 241 nm.

The absorption spectrum of the resulting photoelectric conversion film was measured by the same method as in Example 3. The measurement results are shown by the broken line graph in FIG. 7A.

As shown by the broken line graph in FIG. 7A, in the photoelectric conversion film of Example 6, an absorption peak was observed near 898 nm.

### Example 7

Quartz glass having a thickness of 0.7 mm was used as a supporting substrate, and a chloroform solution of a mixture of the (SPent)₈Si(OPh-3,5-(COOMe)₂)₂Pc obtained in Example 2 and a PCBM derivative in a weight ratio of 7:3 was applied thereon by a spin coating method to give a photoelectric conversion film having a thickness of 238 nm.

The absorption spectrum of the resulting photoelectric conversion film was measured by the same method as in Example 3. The measurement results are shown by the one-dot chain line graph in FIG. 7A.

As shown by the one-dot chain line graph in FIG. 7A, in the photoelectric conversion film of Example 7, an absorption peak was observed near 906 nm.

### Example 8

Quartz glass having a thickness of 0.7 mm was used as a supporting substrate, and a chloroform solution of a mixture of the (SPent)₈Si(OPh-3,5-(COOMe)₂)₂Pc obtained in Example 2 and a PCBM derivative in a weight ratio of 9:1 was applied thereon by a spin coating method to give a photoelectric conversion film having a thickness of 239 nm.

The absorption spectrum of the resulting photoelectric conversion film was measured by the same method as in Example 3. The measurement results are shown by the two-dot chain line graph in FIG. 7A.

As shown by the two-dot chain line graph in FIG. 7A, in the photoelectric conversion film of Example 8, an absorption peak was observed near 916 nm.

### Photocurrent Multiplication Device

The photocurrent multiplication devices according to the present disclosure will now be described more specifically by showing Examples 9 to 12 and Reference Example 1.

### Example 9

A glass substrate having a thickness of 0.7 mm and provided with an ITO electrode having a thickness of 150 nm was used as a substrate, and this ITO electrode was used as a lower electrode. Furthermore, a film of a mixture of the (OBu)₈Si(OSiHex₃)₂Nc obtained in Example 1 and fullerene C60 was formed as the photoelectric conversion film having a thickness of 325 nm of Example 3 on the ITO electrode by vacuum deposition. Furthermore, an Al electrode having a thickness of 80 nm was formed as an upper electrode on the photoelectric conversion film. The Al electrode was formed at a degree of vacuum of 5.0×10⁴ Pa or less and at a deposition rate of 1 angstrom/s to give a photocurrent multiplication device.

### Measurement of Spectral Sensitivity

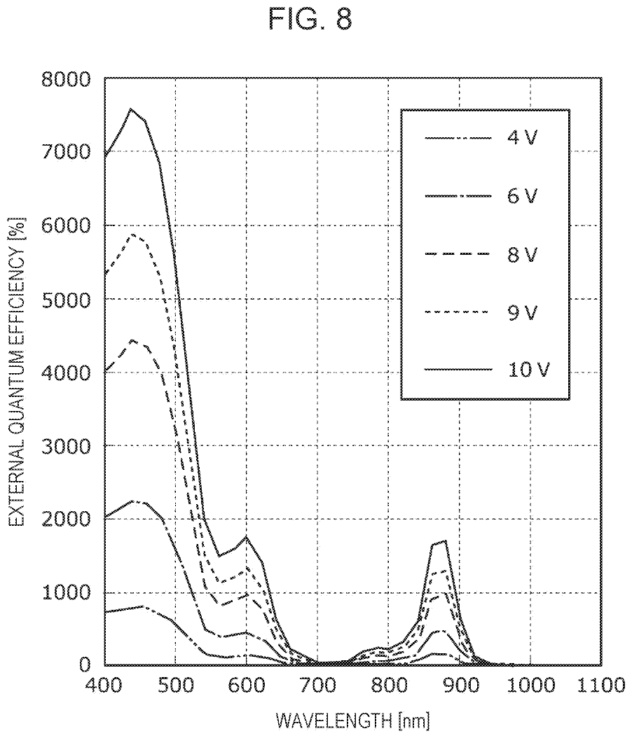

The spectral sensitivity of the obtained photocurrent multiplication device was measured. The measurement used a long-wavelength corresponding type spectral sensitivity measuring apparatus (manufactured by Bunkoukeiki Co., Ltd., CEP-25RR). More specifically, the photocurrent multiplication device was introduced into a measurement jig that can be sealed in a glove box under a nitrogen atmosphere, and the external quantum efficiency was measured as the spectral sensitivity, which is an indicator of the photoelectric conversion efficiency. The spectral sensitivity was measured under conditions in which bias voltages applied to the photocurrent multiplication device were 4 V, 6 V, 8 V, 9 V, and 10 V. The bias voltages were applied such that the potential of the upper electrode was higher than that of the lower electrode. That is, the external quantum efficiency was measured under conditions in which electrons could be injected from the lower electrode. The measurement results are shown in FIG. 8. The measurement results of the external quantum efficiency at a wavelength of 880 nm during the application of a bias voltage of 10 V are shown in Table 1.

As shown in FIG. 8, in the photocurrent multiplication device of Example 9, the quantum efficiency in the visible light region was the highest, about 7580%, at a wavelength of near 440 nm during the application of a bias voltage of 10 V. In the photocurrent multiplication device of Example 9, the external quantum efficiency in the near-infrared light region was the highest, about 1680%, at a wavelength of near 880 nm during the application of a bias voltage of 10 V. In addition, in the photocurrent multiplication device of Example 9, the external quantum efficiency in the near-infrared light region was 166% at a wavelength of 760 nm during the application of a bias voltage of 10 V, and it was demonstrated that electrons were injected from the lower electrode even at a wavelength of 760 nm or more to exhibit a photocurrent multiplication effect.

### Measurement of Dark Current

The obtained photocurrent multiplication device was measured for dark current. The measurement used a semiconductor parameter analyzer (manufactured by Keysight Technologies, P1500A). More specifically, the photocurrent multiplication device was introduced into a measurement jig that can be sealed in a glove box under a nitrogen atmosphere, covered with a black curtain, and subjected to current-voltage measurement during the dark time. The measurement results of dark current during the application of a bias voltage of 10 V are shown in Table 1. As shown in Table 1, the dark current value of the photocurrent multiplication device of Example 9 was 5.3×10−6 mA/cm² at a bias voltage of 10 V.

### Example 10

A glass substrate having a thickness of 0.7 mm and provided with an ITO electrode having a thickness of 150 nm was used as a substrate, and this ITO electrode was used as a lower electrode. Furthermore, a film of a mixture of the (OBu)₈Si(OSiHex₃)₂Nc obtained in Example 1 and fullerene C60 was formed as the photoelectric conversion film having a thickness of 325 nm of Example 3 on the ITO electrode by vacuum deposition. Furthermore, a film of fullerene C60 was formed at a thickness of 10 nm as an upper buffer layer on the photoelectric conversion film. The upper buffer layer of fullerene C60 was formed at a degree of vacuum of 5.0×10⁻⁴ Pa or less and at a deposition rate of 0.5 angstrom/s. Furthermore, an Al electrode having a thickness of 80 nm was formed as an upper electrode on the upper buffer layer. The Al electrode was formed at a degree of vacuum of 5.0×10⁻⁴ Pa or less and at a deposition rate of 1 angstrom/s to provide a photocurrent multiplication device.

The spectral sensitivity and dark current of the obtained photocurrent multiplication device were measured by the same method as in Example 9. The measurement results of the external quantum efficiency at a wavelength of 880 nm during the application of a bias voltage of 10 V and the dark current during the application of a bias voltage of 10 V are shown in Table 1. In the photocurrent multiplication device of Example 10, the quantum efficiency in the visible light region was high, about 1520%, at a wavelength of near 440 nm during the application of a bias voltage of 10 V. In the photocurrent multiplication device of Example 10, the external quantum efficiency in the near-infrared light region was the highest, about 668%, at a wavelength of near 880 nm during the application of a bias voltage of 10 V. In the photocurrent multiplication device of Example 10, the dark current value at a bias voltage of 10 V was 4.5×10⁻⁶ mA/cm².

### Reference Example 1

A glass substrate having a thickness of 0.7 mm and provided with an ITO electrode having a thickness of 150 nm was used as a substrate, and this ITP electrode was used as a lower electrode. Furthermore, a film of 9,9′-[1,1′-biphenyl]-4,4′-diylbis[3,6-bis(1,1-dimethylethyl)]-9H-carbazol (manufactured by Sigma-Aldrich Co., LLC, CAS838862-47-8) was formed at a thickness of 30 nm as a lower buffer layer on the ITO electrode by vacuum deposition. The lower buffer layer of 9,9′-[1,1′-biphenyl]-4,4′-diylbis[3,6-bis(1,1-dimethylethyl)]-9H-carbazol was formed at a degree of vacuum of 5.0×10⁴ Pa or less and at a deposition rate of 0.5 angstrom/s. Subsequently, a film of a mixture of the (OBu)₈Si(OSiHex₃)₂Nc obtained in Example 1 and fullerene C60 was formed as the photoelectric conversion film having a thickness of 325 nm of Example 3 on the lower buffer layer by vacuum deposition. Furthermore, a film of fullerene C60 having a thickness of 10 nm was formed as an upper buffer layer on the photoelectric conversion film. The upper buffer layer of fullerene C60 was formed at a degree of vacuum of 5.0×10⁴ Pa or less and at a deposition rate of 0.5 angstrom/s. Furthermore, an Al electrode having a thickness of 80 nm was formed as an upper electrode on the upper buffer layer. The Al electrode was formed at a degree of vacuum of 5.0×10⁻⁴ Pa or less and at a deposition rate of 1 angstrom/s to provide a photocurrent multiplication device.

The spectral sensitivity and dark current of the obtained photocurrent multiplication device were measured by the same method as in Example 9. The measurement results of the external quantum efficiency at a wavelength of 880 nm during the application of a bias voltage of 10 V and the dark current during the application of a bias voltage of 10 V are shown in Table 1. In the photocurrent multiplication device of Reference Example 1, the quantum efficiency in the visible light region was high, about 9%, at near 440 nm during the application of a bias voltage of 10 V. In addition, in the photocurrent multiplication device of Reference Example 1, the external quantum efficiency in the near-infrared light region was the highest, about 2%, at a wavelength of near 880 nm during the application of a bias voltage of 10 V. In the photocurrent multiplication device of Reference Example 1, the dark current value at a bias voltage of 10 V was 2.1×10⁻⁶ mA/cm².

TABLE 1

| | | External quantum | Dark current |
|---|---|---|---|
| | | efficiency at 880 nm [%] | [mA/cm²] |
| Example 9 | Absence of upper buffer layer | 1680 | 5.3 × 10⁻⁶ |
| | Absence of lower buffer layer | | |
| Example 10 | Presence of upper buffer layer | 668 | 4.5 × 10⁻⁶ |
| | Absence of lower buffer layer | | |
| Reference | Presence of upper buffer layer | 2 | 2.1 × 10⁻⁶ |
| Example 1 | Presence of lower buffer layer | | |

It was demonstrated by the results above that the photocurrent multiplication device of Example 10 can reduce the dark current by introducing an upper buffer layer while maintaining the photocurrent multiplication effect that achieves an external quantum efficiency of 100% or more.

In contrast, in the photocurrent multiplication device of Reference Example 1, the results were that although the dark current can be further reduced by introducing a lower buffer layer, a photocurrent multiplication effect was not obtained. This is inferred that the lower buffer layer acts as a barrier to block the electron injection from the lower electrode. Accordingly, it was demonstrated that the external quantum efficiency can be improved when the lower electrode and the photoelectric conversion film are in contact with each other.

However, in Reference Example 1, it is inferred that since the lower buffer layer had a relatively large thickness of 30 nm and 9,9′-[1,1′-biphenyl]-4,4′-diylbis[3,6-bis(1,1-dimethylethyl)]-9H-carbazol used as the lower buffer layer had a shallow LUMO energy level of 2.7 eV, the effect of blocking the electron injection by the lower buffer layer was large.

Here, it is thought that when the thickness of the lower buffer layer is 10 nm or less, electron injection is likely to occur by a tunnel effect. In addition, it is thought that since a portion where the film thickness is small is locally present due to a variation in the thickness of the lower buffer layer and electron injection from the thin portion can be expected, the electron injection occurs by a tunnel effect even if the thickness is 20 nm or less.

In addition, it is thought that when a lower buffer layer having a LUMO energy level that is similar to the LUMO energy level of the photoelectric conversion film is used, electron injection with a similar level to that when electrons are injected into the photoelectric conversion film occurs. Accordingly, it is thought that when the difference between the LUMO energy level of the lower buffer layer and the LUMO energy level of the photoelectric conversion film is 0.5 eV or less, electron injection occurs.

It is therefore thought that even when a lower buffer layer is introduced for the purpose of, for example, suppressing the transmission of heat to the photoelectric conversion film and increasing the heat resistance of the photocurrent multiplication device, if the thickness of the lower buffer layer is 20 nm or less or the difference between the LUMO energy level of the lower buffer layer and the LUMO energy level of the photoelectric conversion film is 0.5 eV or less, the photocurrent multiplication phenomenon is unlikely to be blocked and the external quantum efficiency can be improved.

### Example 11

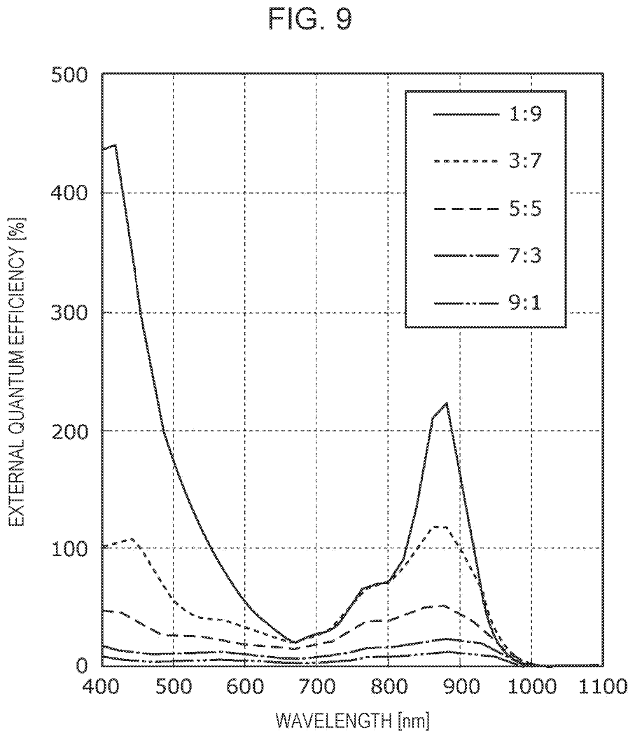

A glass substrate having a thickness of 0.7 mm and provided with an ITO electrode having a thickness of 150 nm was used as a substrate, and this ITP electrode was used as a lower electrode. Furthermore, a photoelectric conversion film having a thickness of 211 nm was produced on the ITO electrode using the (SPent)₈Si(OPh-3,5-(COOMe)₂)₂Pc obtained in Example 2 and a PCBM derivative in a weight ratio of 1:9 as the materials for the photoelectric conversion film by the same method as in Example 4. Subsequently, on the photoelectric conversion film, an Al electrode having a thickness of 80 nm was formed as an upper electrode by vacuum deposition of the same method as in Example 9. The spectral sensitivity of the obtained photocurrent multiplication device was measured by the same method as in Example 9. The measurement results during the application of a bias voltage of 10 V are shown in FIG. 9 and Table 2. The ratios shown by the legend in FIG. 9 are the weight ratios of the (SPent)₈Si(OPh-3,5-(COOMe)₂)₂Pc and the PCBM derivative corresponding to Examples 11 to 15.

As shown by the solid line graph in FIG. 9, in the photocurrent multiplication device of Example 11, the highest external quantum efficiency was about 440% at near 420 nm during the application of a bias voltage of 10 V, and the next highest external quantum efficiency was about 224% at a wavelength of near 880 nm. In addition, the dark current of the photocurrent multiplication device of Example 11 was 4.6×10⁻² mA/cm² during the application of a bias voltage of 10 V.

### Examples 12 to 15

Photocurrent multiplication devices of Examples 12 to 15 were obtained by the same method as in Example 11 except that a chloroform solution of a mixture of the ((SPent)₈Si(OPh-3,5-(COOMe)₂)₂Pc obtained in Example 2 and the PCBM derivative as the materials for the photoelectric conversion film was applied in a weight ratio of 3:7, 5:5, 7:1, or 9:1 instead of the weight ratio of 1:9 by a spin coating method. The photocurrent multiplication devices of Examples 12 to 15 included the photoelectric conversion film having a thickness of 233 nm of Example 5, the photoelectric conversion film having a thickness of 241 nm of Example 6, the photoelectric conversion film having a thickness of 237 nm of Example 7, and the photoelectric conversion film having a thickness of 239 nm of Example 8, respectively.

The spectral sensitivities of the obtained photocurrent multiplication devices were measured as in Example 9. The measurement results of Examples 12 to 15 are shown in FIG. 9 and Table 2.

As shown in Table 2, in the photocurrent multiplication devices of Examples 11 to 15 including the photoelectric conversion films of the ((SPent)₈Si(OPh-3,5-(COOMe)₂)₂Pc and the PCBM derivative in weight ratios of 1:9, 3:7, 5:5, 7:1, and 9:1, respectively, had external quantum efficiencies of about 224%, 118%, 50%, 23%, and 12%, respectively, at a wavelength of near 880 nm.

TABLE 2

Weight ratio in photoelectric conversion film

| Phthalocyanine | PCBM | External quantum |
|---|---|---|
| derivative | derivative | efficiency |
| [wt %] | [wt %] | at 880 nm [%] |
| 10 | 90 | 224 |
| 30 | 70 | 118 |
| 50 | 50 | 50 |
| 70 | 30 | 23 |
| 90 | 10 | 12 |

The dark current of the photocurrent multiplication device of Example 12 including the photoelectric conversion film having the weight ratio of 3:7 was 6.1×10⁻² mA/cm² during the application of a bias voltage of 10 V.

From the results above, the photocurrent multiplication devices of Examples 9 to 15 can reduce the dark current compared to the known configurations disclosed in Non-Patent Literatures 4 and 6. Thus, it is suggested that in a photocurrent multiplication device having a configuration in which electrons injected from the lower electrode flow by trapping holes generated by photoelectric conversion in the photoelectric conversion film, the dark current can be reduced.

Since the dark current of the photocurrent multiplication device of Example 11 in which the weight ratio was 1:9 was lower than that of the photocurrent multiplication device of Example 12 in which the weight ratio was 3:7, it is suggested that in a photocurrent multiplication device including a photoelectric conversion film that is more likely to become a sea-island structure and has less paths in which electron charges flow during the dark time, the dark current is reduced.

Consequently, it was demonstrated that when the concentration of the phthalocyanine derivative as the donor material in the photoelectric conversion film is 30 wt % or less, photocurrent multiplication characteristics in which the external quantum efficiency is 100% or more are exhibited. Accordingly, it is suggested that when the weight ratio of the donor material to the acceptor material in the photoelectric conversion film is 3:7 or less, i.e., 3/7 or less, the amount of the donor material in the photoelectric conversion film is decreased, and the photoelectric conversion film has a sea-island structure in which the donor material is island-shaped.

The photocurrent multiplication device and the imaging device according to the present disclosure have been described above based on embodiments and examples, but the present disclosure is not limited to these embodiments and examples. Unless departing from the scope of the present disclosure, embodiments and examples with various modifications concerned by those skilled in the art and other aspects constructed by combining some of the components in the embodiments and examples are also included in the scope of the present disclosure.

Incidentally, the compositions and photoelectric conversion films according to the present disclosure may be utilized in solar cells by extracting electric charged generated by light as energy.

The composition according to the present disclosure may be utilized for films, sheets, glass, building materials, and so on as a near-infrared light cutting material. The composition may be used as an infrared absorbent by mixing with an ink, resin, glass, or the like.

The composition, photocurrent multiplication device, and imaging device according to the present disclosure can be applied to an image sensor or the like, for example, an image sensor having high photoelectric conversion characteristics in a near-infrared light region.

What is claimed is:

1. A photocurrent multiplication device having an external quantum efficiency of 100% or more, comprising:
at least one first electrode;
at least one second electrode that faces the at least one first electrode; and
a photoelectric conversion film that is located between the at least one first electrode and the at least one second electrode and that includes a donor material and an acceptor material, wherein
the photoelectric conversion film at least partially has a sea-island structure in which the donor material is interspersed in the photoelectric conversion film.

2. A photocurrent multiplication device having an external quantum efficiency of 100% or more, comprising:
at least one first electrode;
at least one second electrode that faces the at least one first electrode;
a photoelectric conversion film that is located between the at least one first electrode and the at least one second electrode and that includes a donor material and an acceptor material; and
a buffer layer that is located between the at least one first electrode and the photoelectric conversion film, wherein
the photoelectric conversion film has a bulk heterojunction structure, and
a difference between an energy level of a lowest unoccupied molecular orbital of the buffer layer and an energy level of a lowest unoccupied molecular orbital of the photoelectric conversion film is 0.5 eV or less.

3. The photocurrent multiplication device according to claim 1, wherein
a weight ratio of the donor material to the acceptor material in the photoelectric conversion film is 3/7 or less.

4. The photocurrent multiplication device according to claim 1, wherein
a weight ratio of the donor material to the acceptor material in the photoelectric conversion film is 1/9 or less.

5. The photocurrent multiplication device according to claim 1, wherein
the donor material is an organic semiconductor material.

6. The photocurrent multiplication device according to claim 5, wherein
the donor material is a low-molecular material.

7. The photocurrent multiplication device according to claim 5, wherein
the donor material includes at least one substituent not including a π-conjugated system.

8. The photocurrent multiplication device according to claim 5, wherein
the donor material includes at least one alkyl group including 4 or more carbon atoms.

9. The photocurrent multiplication device according to claim 5, wherein
the donor material includes a phthalocyanine skeleton or a naphthalocyanine skeleton.

10. The photocurrent multiplication device according to claim 1, wherein
the external quantum efficiency of the photocurrent multiplication device in a wavelength region of 760 nm or more is 100% or more.

11. The photocurrent multiplication device according to claim 1, wherein
the photoelectric conversion film has a structure in which the donor material is dispersed throughout the photoelectric conversion film.

12. The photocurrent multiplication device according to claim 1, wherein
at least one selected from the group consisting of the at least one first electrode and the at least one second electrode is in contact with the photoelectric conversion film.

13. The photocurrent multiplication device according to claim 1, further comprising:
a buffer layer located between the at least one first electrode and the photoelectric conversion film or between the at least one second electrode and the photoelectric conversion film.

14. The photocurrent multiplication device according to claim 1, wherein
the at least one first electrode has a work function that is deeper by 0.6 eV or more than the energy level of the lowest unoccupied molecular orbital of the photoelectric conversion film.

15. The photocurrent multiplication device according to claim 1, wherein
the at least one first electrode or the at least one second electrode includes a plurality of pixel electrodes, and
the plurality of pixel electrodes is arranged in an array.

16. The photocurrent multiplication device according to claim 1, wherein
the external quantum efficiency of the photocurrent multiplication device is 100% or more when an electron injected from the at least one first electrode into the photoelectric conversion film is transported toward the at least one second electrode.

17. An imaging device comprising:
a substrate; and
a pixel including an electric charge detection circuit disposed in the substrate, a photoelectric converter provided on the substrate, and an electric charge storage node electrically connected to the electric charge detection circuit and the photoelectric converter, wherein
the photoelectric converter includes the photocurrent multiplication device according to claim 1.

18. The photocurrent multiplication device according to claim 1, wherein
the external quantum efficiency of the photocurrent multiplication device in a wavelength region of 760 nm or more is 200% or more.

19. The photocurrent multiplication device according to claim 1, wherein
the photocurrent multiplication device has an absorption peak in a wavelength region of 760 nm or more.

20. The photocurrent multiplication device according to claim 1, wherein
the photocurrent multiplication device has an absorption peak in a wavelength region of 880 nm or more.
